(19) United States
(12) Patent Application Publication
(10) Pub. No.: US 2025/0258508 A1
(43) Pub. Date: Aug. 14, 2025

(54) TEMPERATURE CONTROL DEVICE

(71) Applicant: SHINWA CONTROLS CO., LTD., Kawasaki-shi, Kanagawa (JP)

(72) Inventors: Michio TAKAYAMA, Kawasaki-shi (JP); Isamu SASAKI, Kawasaki-shi (JP)

(73) Assignee: SHINWA CONTROLS CO., LTD., Kawasaki-shi, Kanagawa (JP)

(21) Appl. No.: 18/856,514

(22) PCT Filed: Apr. 18, 2023
(86) PCT No.: PCT/JP2023/015437

§ 371 Date: Oct. 11, 2024

(30) Foreign Application Priority Data
Apr. 22, 2022 (JP) 2022-070857

(51) Int. Cl. G05D 23/13; F16K 11/085

(52) U.S. Cl. CPC G05D 23/1373; F16K 11/0853

(57) ABSTRACT

Provided is a temperature control device capable of controlling, with high accuracy, a temperature of a fluid for temperature control to be supplied to a temperature control target in comparison to a case in which there is not provided control means for controlling temperature adjustment performance of supply means based on a result of detection performed by detection means for detecting a heat load of the temperature control target. The temperature control device includes: supply means for adjusting a fluid for temperature control to a predetermined temperature and then supplying the fluid for temperature control; detection means for detecting a heat load of a temperature control target to be supplied with the fluid for temperature control from the supply means, the detection means being arranged on the temperature control target side; and control means for controlling temperature adjustment performance of the supply means based on a result of detection performed by the detection means.

### TECHNICAL FIELD

The present invention relates to a temperature control device.

### BACKGROUND ART

Hitherto, as a technology relating to a temperature control device, there have already been proposed, for example, temperature control devices disclosed in Patent Literature 1 and Patent Literature 2.

### BACKGROUND ART

A temperature adjustment device described in Patent Literature 1 includes: a temperature-adjusted member including a member flow passage therein; a first temperature control portion that controls a temperature of a first temperature adjustment medium to a first temperature; a second temperature control portion that controls a temperature of a second temperature adjustment medium to a second temperature different from the first temperature; a first flow passage that allows the first temperature adjustment medium to flow between the member flow passage and the first temperature control portion; a second flow passage that allows the second temperature adjustment medium to flow between the member flow passage and the second temperature control portion; a third flow passage that allows the first temperature adjustment medium to flow through the first temperature control portion without passing through the member flow passage; a fourth flow passage that allows the second temperature adjustment medium to flow through the second temperature control portion without passing through the member flow passage; a first three-way valve provided at a branching portion from which the first flow passage and the third flow passage extend; a second three-way valve provided at a branching portion from which the second flow passage and the fourth flow passage extend; and a third three-way valve provided at a branching portion from which the first flow passage and the second flow passage extend.

A temperature control method described in Patent Literature 2 includes: a switching step of switching a heating medium, which is arranged in a treatment container of a plasma treatment apparatus and is to be supplied to a flow passage provided inside a placement table on which a board is to be placed, from the heating medium having a first temperature supplied from a first temperature control portion when an etching process is performed on the board to the heating medium having a second temperature supplied from a second temperature control portion when cleaning treatment for removing a reaction product adhering to an electrostatic chuck provided in an upper part of the placement table after the board is taken out of the treatment container; an ignition step of starting supply of a cleaning gas into the treatment container and igniting plasma; a gradient calculating step of calculating a gradient of a temperature change of the heating medium based on a temperature of the heating medium on an outlet side of the flow passage; a first control step of controlling the second temperature control portion until the temperature of the heating medium on the outlet side of the flow passage is stabilized to be a third temperature lower than a predetermined set value; and a second control step of controlling the second temperature control portion so that the temperature of the heating medium on the outlet side of the flow passage becomes equal to the set value.

### CITATION LIST

### Patent Literature

[PTL 1] JP 2020-107684 A
[PTL 2] JP 2021-145095 A

### SUMMARY OF INVENTION

### Technical Problem

The present invention has an object to provide a temperature control device capable of controlling, with high accuracy, a temperature of a fluid for temperature control to be supplied to a temperature control target in comparison to a case in which there is not provided control means for controlling temperature adjustment performance of supply means based on a result of detection performed by detection means for detecting a heat load of the temperature control target.

### Solution to Problem

According to the invention of claim 1, there is provided a temperature control device, including: supply means for adjusting a fluid for temperature control to a predetermined temperature and then supplying the fluid for temperature control; detection means for detecting a heat load of a temperature control target to be supplied with the fluid for temperature control from the supply means, the detection means being arranged on the temperature control target side; and control means for controlling temperature adjustment performance of the supply means based on a result of detection performed by the detection means.

According to the invention of claim 2, in the temperature control device as described in claim 1, the detection means includes: a first three-way valve for flow rate control configured to split the fluid for temperature control from the supply means into the fluid for temperature control to be supplied to the temperature control target and the fluid for temperature control to be returned to the supply means without being supplied to the temperature control target; first temperature detection means for detecting a temperature of the fluid for temperature control to be supplied to the temperature control target by the first three-way valve for flow rate control; and second temperature detection means for detecting a temperature of the fluid for temperature control returned from the temperature control target.

According to the invention of claim 3, in the temperature control device as described in claim 1, the supply means includes: first supply means for supplying a lower temperature fluid adjusted to a first predetermined lower temperature; and second supply means for supplying a higher temperature fluid adjusted to a second predetermined higher temperature, and wherein the detection means includes: a second three-way valve for flow rate control configured to mix the lower temperature fluid supplied from the first supply means and the higher temperature fluid supplied from the second supply means while controlling a flow rate of the lower temperature fluid and a flow rate of the higher temperature fluid to form the fluid for temperature control and then supply the fluid for temperature control to the temperature control target; a third three-way valve for flow rate control configured to distribute the fluid for temperature control having flowed through the temperature control target to the first supply means and the second supply means while controlling a flow rate of the fluid for temperature control; first temperature detection means for detecting a temperature of the fluid for temperature control to be supplied to the temperature control target by the second three-way valve for flow rate control; and second temperature detection means for detecting a temperature of the fluid for temperature control returned from the temperature control target.

According to the invention of claim 4, in the temperature control device as described in any one of claims 1 to 3, the control means controls the temperature adjustment performance of the supply means by increasing and decreasing a flow rate of a heat exchange medium that adjusts a temperature of the fluid for temperature control through intermediation of a heat exchanger in the supply means.

According to the invention of claim 5, in the temperature control device as described in claim 2, the control means calculates the heat load of the temperature control target based on a flow rate of the fluid for temperature control to be supplied to the temperature control target and results of detection performed by the first temperature detection means and the second temperature detection means, which are included in distribution information of the first three-way valve for flow rate control.

According to the invention of claim 6, in the temperature control device as described in claim 5, the control means controls temperature adjustment performance F1 of the supply means based on a result H1 of calculation of the heat load of the temperature control target by an arithmetic expression:

F1=((H1−b)/a)^{0.5}

According to the invention of claim 7, in the temperature control device as described in claim 6, the control means controls an rpm of a drive source configured to drive a chiller in the supply means.

According to the invention of claim 8, in the temperature control device as described in claim 1, the control means controls a distribution ratio at the first three-way valve for flow rate control.

According to the invention of claim 9, in the temperature control device as described in claim 1, the supply means includes a fourth three-way valve for flow rate control configured to split the fluid for temperature control from the supply means into the fluid for temperature control to be supplied to the temperature control target and the fluid for temperature control to be returned without being supplied to the temperature control target.

According to the invention of claim 10, in the temperature control device as described in claim 9, the control means controls a flow rate of the fluid for temperature control flowing into the fourth three-way valve for flow rate control to a constant value.

According to the invention of claim 11, in the temperature control device as described in claim 1, the supply means includes: a storage tank configured to store the fluid for temperature control returned from the temperature control target; and cooling means for cooling the fluid for temperature control stored in the storage tank.

According to the invention of claim 12, in the temperature control device as described in claim 2, the first three-way valve for flow rate control includes: an inflow port, which allows inflow of the fluid for temperature control; and a first valve port and a second valve port, which allow the fluid for temperature control flowing in through the inflow port to be split into the fluid for temperature control to be supplied to the temperature control target and the fluid for temperature control to be returned to the supply means without being supplied to the temperature control target.

### Advantageous Effects of Invention

According to the present invention, the temperature control device capable of controlling, with high accuracy, the temperature of a fluid for temperature control to be supplied to the temperature control target in comparison to a case in which there is not provided control means for controlling temperature adjustment performance of supply means based on a result of detection performed by detection means for detecting a heat load of the temperature control target can be provided.

### BRIEF DESCRIPTION OF DRAWINGS

FIG. 1 is a schematic configuration diagram for illustrating a constant-temperature maintaining device (chiller device) as a temperature control device according to a first embodiment of the present invention.

FIG. 2 is a circuit configuration diagram for illustrating a refrigerator of the constant-temperature maintaining device (chiller device) as the temperature control device according to the first embodiment of the present invention.

FIG. 3 is a sectional configuration view for illustrating a plasma treatment apparatus.

FIG. 4 is a schematic configuration diagram for illustrating an operation of the constant-temperature maintaining device (chiller device) as the temperature control device according to the first embodiment of the present invention.

FIG. 5 is a characteristic graph for showing an operation of the constant-temperature maintaining device (chiller device) as the temperature control device according to the first embodiment of the present invention.

FIG. 6 is a characteristic graph for showing an operation of a related-art chiller device.

FIG. 7 is a schematic configuration diagram for illustrating a constant-temperature maintaining device (chiller device) as a temperature control device according to a second embodiment of the present invention.

FIG. 8 is a graph for showing temperature characteristics of the chiller device.

FIG. 9 is a schematic configuration diagram for illustrating an operation of the constant-temperature maintaining device (chiller device) as the temperature control device according to the second embodiment of the present invention.

FIG. 10 is a schematic configuration diagram for illustrating the operation of the constant-temperature maintaining device (chiller device) as the temperature control device according to the second embodiment of the present invention.

FIG. 11 is a graph for showing switching characteristics of a three-way valve for flow rate control.

FIG. 12(a) is a front view for illustrating a three-way motor valve as one example of the three-way valve for flow rate control according to the first embodiment of the present invention.

FIG. 12(b) is a left side view for illustrating the three-way motor valve as one example of the three-way valve for flow rate control according to the first embodiment of the present invention.

FIG. 12(c) is a bottom view of an actuator, for illustrating the three-way motor valve as one example of the three-way valve for flow rate control according to the first embodiment of the present invention.

FIG. 13 is a sectional view taken along the line A-A of FIG. 12(b), for illustrating the three-way motor valve as one example of the three-way valve for flow rate control according to the first embodiment of the present invention.

FIG. 14 is a sectional view taken along the line B-B of FIG. 12(a), for illustrating the three-way motor valve as one example of the three-way valve for flow rate control according to the first embodiment of the present invention.

FIG. 15 is a sectional perspective view for illustrating relevant parts of the three-way motor valve as one example of the three-way valve for flow rate control according to the first embodiment of the present invention.

FIG. 16(a) is a perspective configuration view for illustrating a valve seat.

FIG. 16(b) is a front configuration view for illustrating the valve seat.

FIG. 17 is a configuration view for illustrating a relationship between the valve seat and a valve shaft.

FIG. 18(a) is a partially cutaway perspective configuration view for illustrating an spring energized seal.

FIG. 18(b) is a sectional configuration view for illustrating the spring energized seal.

FIG. 19 is a sectional view for illustrating the spring energized seal under a mounted state.

FIG. 20 is a configuration view for illustrating a modification example of the spring energized seal.

FIG. 21(a) is a perspective configuration view for illustrating a wave washer.

FIG. 21(b) is a side configuration view for illustrating the wave washer.

FIG. 21(c) is a partially cutaway front configuration view for illustrating the wave washer.

FIG. 22 is a perspective configuration view for illustrating an adjusting ring.

FIG. 23(a) is a configuration view for illustrating a motion of the valve shaft.

FIG. 23(b) is a configuration view for illustrating the motion of the valve shaft.

FIG. 24(a) is a perspective configuration view for illustrating the valve shaft.

FIG. 24(b) is a front configuration view for illustrating the valve shaft.

FIG. 25(a) is a configuration view for illustrating the motion of the valve shaft.

FIG. 25(b) is a configuration view for illustrating the motion of the valve shaft.

FIG. 26 is a sectional configuration view for illustrating a motion of the three-way motor valve as one example of the three-way valve for flow rate control according to the first embodiment of the present invention.

### DESCRIPTION OF EMBODIMENTS

In the following, embodiments of the present invention are described with reference to the drawings.

### First Embodiment

### <Schematic Configuration of Chiller Device>

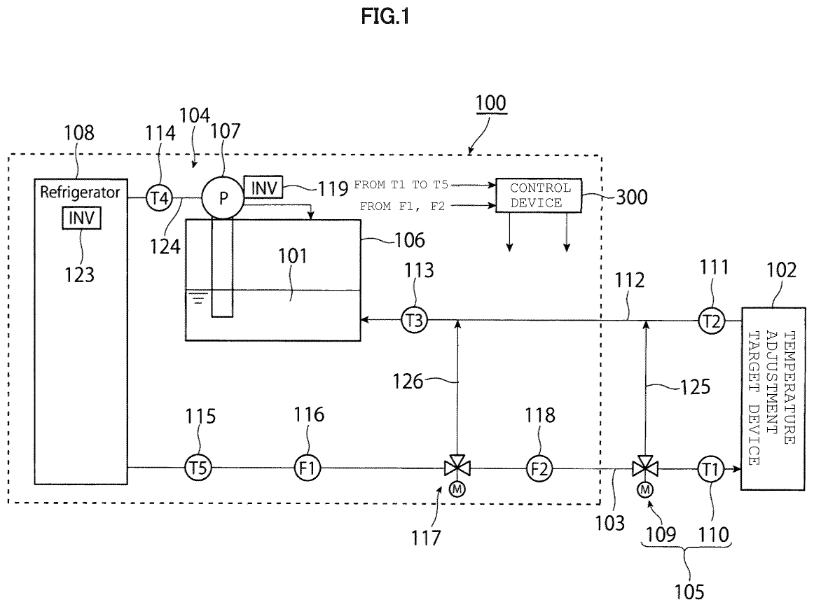

FIG. 1 is a schematic configuration diagram for illustrating a constant-temperature maintaining device (chiller device) as one example of a temperature control device according to a first embodiment of the present invention.

A chiller device 100 is used for, for example, a semiconductor manufacturing apparatus involving plasma etching as described later, and is configured to perform control so as to maintain, for example, a temperature of a semiconductor wafer as one example of a temperature control target (workpiece) W to a constant temperature.

As illustrated in FIG. 1, the chiller device 100 mainly includes a fluid supply portion 104, detection means 105, and a control device 300. The fluid supply portion 104 is one example of supply means for adjusting a temperature of a fluid 101 for temperature control to a predetermined temperature and then supplying the fluid 101 for temperature control to a temperature adjustment target device 102 via a supply pipe 103. The temperature adjustment target device 102 is one example of the temperature control target. The detection means 105 for detecting a heat load of the temperature adjustment target device 102 is provided outside the chiller device 100 and is arranged closest to the temperature adjustment target device 102 on the temperature adjustment target device 102 side. The temperature adjustment target device 102 is supplied with the fluid 101 for temperature control by the fluid supply portion 104. The control device 300 is one example of control means for controlling temperature adjustment performance of the fluid supply portion 104 based on a result of detection performed by the detection means 105.

The fluid supply portion 104 includes a storage tank 106, a supply pump 107, and a refrigerator 108. The storage tank 106 is configured to store the fluid 101 for temperature control. The supply pump 107 supplies the fluid 101 for temperature control from the storage tank 106. The refrigerator 108 cools the fluid 101 for temperature control supplied by the supply pump 107 to a temperature instructed by the control device 300.

The detection means 105 includes a first three-way valve 109 for flow rate control, a first temperature sensor 110, and a second temperature sensor 111. The first three-way valve 109 for flow rate control is configured to split the fluid 101 for temperature control into the fluid 101 for temperature control to be supplied from the chiller device 100 to the temperature adjustment target device 102 and the fluid 101 for temperature control to be returned to the storage tank 106 via a return pipe 112 without being supplied to the temperature adjustment target device 102. The first temperature sensor 110 is one example of first temperature detection means for detecting a temperature of the fluid 101 for temperature control immediately before being supplied to the temperature adjustment target device 102. The second temperature sensor 111 is one example of second temperature detection means for detecting the temperature of the fluid 101 for temperature control immediately after flowing out from the temperature adjustment target device 102. An outflow portion for return of the first three-way valve 109 for flow rate control is connected to the return pipe 112 through intermediation of a first bypass pipe 125.

The detection means 105 detects the heat load of the temperature adjustment target device 102. The first three-way valve 109 for flow rate control determines a ratio (distribution ratio) of the fluid 101 for temperature control to be supplied to the temperature adjustment target device 102 to the fluid 101 for temperature control flowing into the first three-way valve 109 for flow rate control. Thus, when a flow rate of the fluid 101 for temperature control flowing into the first three-way valve 109 for flow rate control is known, a flow rate of the fluid 101 for temperature control to be supplied to the temperature adjustment target device 102 is obtained. Further, a temperature change ΔT=(Ret Temp1−Sup Temp1), which is caused along with passage of the fluid 101 for temperature control through the temperature adjustment target device 102, is obtained by calculating a difference between a temperature (Sup Temp1) of the fluid 101 for temperature control immediately before being supplied to the temperature adjustment target device 102, which is detected by the first temperature sensor 110, and a temperature (Ret Temp1) of the fluid 101 for temperature control immediately after flowing out from the temperature adjustment target device 102, which is detected by the second temperature sensor 111. As a result, a heat load H1 of the temperature adjustment target device 102 is detected (calculated) by the following arithmetic expression (1) based on the flow rate of the fluid 101 for temperature control flowing into the first three-way valve 109 for flow rate control, the distribution ratio of the fluids 101 for temperature control at the first three-way valve 109 for flow rate control, and the difference between the temperature of the fluid 101 for temperature control detected by the first temperature sensor 110 and the temperature of the fluid 101 for temperature control detected by the second temperature sensor 111.

$$H 1 = m \cdot c \cdot Δ T \qquad ( 1 )$$

Here, “m” represents a mass flow rate (Kg/h) of the fluid 101 for temperature control, that is, a result of multiplication of a flow rate of the fluid 101 for temperature control per unit time by a specific gravity, and “c” represents a specific heat (Kw/Kg/° C.) of the fluid 101 for temperature control.

If the temperature (Sup Temp1) of the fluid 101 for temperature control immediately before being supplied to the temperature adjustment target device 102 and the temperature (Ret Temp1) of the fluid 101 for temperature control immediately after flowing out from the temperature adjustment target device 102 are equal to each other, the heat load H1 of the temperature adjustment target device 102 is zero.

Meanwhile, when the temperature difference (Ret Temp1−Sup Temp1) between the temperature (Sup Temp1) of the fluid 101 for temperature control immediately before being supplied to the temperature adjustment target device 102 and the temperature (Ret Temp1) of the fluid 101 for temperature control immediately after flowing out from the temperature adjustment target device 102 has a large value and/or a flow rate Q1 of the fluid 101 for temperature control is large, the heat load H1 of the temperature adjustment target device 102 is large.

Further, a third temperature sensor 113 is one example of third temperature detection means for detecting the temperature of the fluid 101 for temperature control and is arranged at an inflow portion immediately before the fluid 101 for temperature control is returned to the storage tank 106 via the return pipe 112.

Further, a fourth temperature sensor 114 is one example of fourth temperature detection means for detecting the temperature of the fluid 101 for temperature control supplied from the storage tank 106 and is arranged in a pipe 124 for allowing the fluid 101 for temperature control to be supplied from the storage tank 106 to the refrigerator 108 by the supply pump 107.

A fifth temperature sensor 115 and a first flow rate sensor 116 are arranged in a most upstream portion of the supply pipe 103 through which the fluid 101 for temperature control flowing out from the refrigerator 108 flows. The fifth temperature sensor 115 is one example of fifth temperature detection means for detecting the temperature of the fluid 101 for temperature control immediately after flowing out from the refrigerator 108. The first flow rate sensor 116 is one example of first flow rate detection means for detecting the flow rate of the fluid 101 for temperature control flowing out from the refrigerator 108.

Inside the fluid supply portion 104, there is provided a second three-way valve 117 for flow rate control that splits the fluid 101 for temperature control cooled by the refrigerator 108 into the fluid 101 for temperature control to be supplied toward the temperature adjustment target device 102 and the fluid 101 for temperature control to be returned to the storage tank 106 via the return pipe 112 without being supplied toward the temperature adjustment target device 102. A second flow rate sensor 118 is one example of second flow rate detection means for detecting a flow rate of the fluid 101 for temperature control supplied from the fluid supply portion 104, and is arranged on an outflow side of the second three-way valve 117 for flow rate control toward the temperature adjustment target device 102. An outflow portion for return of the second three-way valve 117 for flow rate control is connected to the return pipe 112 through intermediation of a second bypass pipe 126.

The supply pump 107 is driven by a first inverter motor 119. Further, the refrigerator 108 is driven by a second inverter motor 123. The first inverter motor 119 and the second inverter motor 123 are driven by drive circuits (not shown), respectively, and their rpms or the like are controlled by the control device 300. The rpms of the first inverter motor 119 and the second inverter motor 123 are controlled by changing frequencies of AC power supplied to the first inverter motor 119 and the second invertor motor 123.

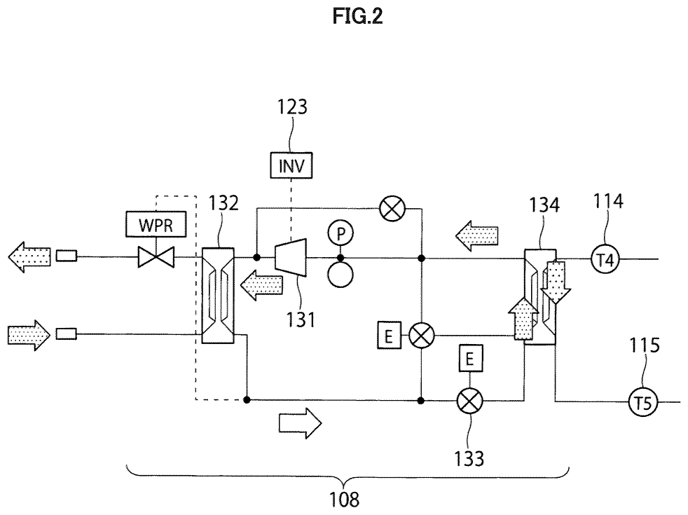

As illustrated in FIG. 2, the refrigerator 108 has the following circuit configuration. Refrigerant gas is compressed by an electric compressor 131 and is sent as a high-pressure gas to a condenser 132 on a discharge side. After the high-pressure gas is condensed in the condenser 132 and is decompressed via an expansion valve 133 of a pressure reducing mechanism, the decompressed gas is sent to an evaporator 134.

The decompressed low-pressure gas is evaporated the evaporator 134 and is sucked into a suction side of the electric compressor 131 so as to repeat the compression again.

The refrigerator 108 cools the fluid 101 for temperature control through a heat exchanger provided in the evaporator 134. The electric compressor 131 is driven by the second inverter motor 123. In the refrigerator 108, a refrigerant condensing effect in the condenser 132 is enhanced by increasing the rpm of the second inverter motor 123, and a refrigerant vaporizing action in the evaporator 134 is increased. As a result, cooling performance is improved.

The first three-way valve 109 for flow rate control can be configured to be switched by the control device 300 so as to increase or decrease the distribution ratio of the fluid 101 for temperature control to be supplied to the temperature adjustment target device 102 in accordance with, for example, the difference (Ret Temp1-Sup Temp1) between the temperature (Sup Temp1) detected by the first temperature sensor 110 and the temperature (Ret Temp1) detected by the second temperature sensor 111.

More specifically, when the temperature (Ret Temp1) detected by the second temperature sensor 111 is higher than the temperature (Sup Temp1) detected by the first temperature sensor 110, the first three-way valve 109 for flow rate control is switched to increase the flow rate of the fluid 101 for temperature control to be supplied to the temperature adjustment target device 102.

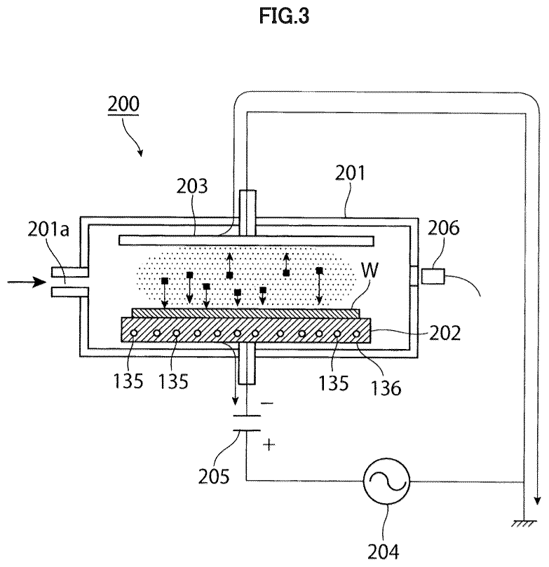

The temperature adjustment target device 102 has a flow passage 135 for temperature control (see FIG. 3) therein. The fluid 101 for temperature control having a temperature adjusted to a predetermined temperature by the fluid supply portion 104 continuously flows through the flow passage 135 for temperature control.

Examples of a heating medium (brine) used as the fluid 101 for temperature control include fluorine-based inert liquids such as Opteon (trademark: manufactured by Chemours-Mitsui Fluoroproducts Co., Ltd.) and Novec (trademark: manufactured by 3M company), which are used, for example, at a pressure of from 0 MPa to 1 MPa and in a temperature range of from about −85° C. to about +120° C.

The control device 300 comprehensively controls an overall operation of the chiller device 100. The control device 300 includes a central processing unit (CPU), a read only memory (ROM), a random access memory (RAM) (not shown), or a bus for connecting the CPU and the ROM, and the like. Detected signals from the first to the fifth temperature sensors 110, 111, 113, 114, and 115, the first flow rate sensor 116 and the second flow rate sensor 118, and the like are input to the control device 300. Further, the control device 300 is configured to control a required arithmetic process or opening degrees (distribution ratios) of the first three-way valve 109 for flow rate control and the second three-way valve 117 for flow rate control based on a program stored in advance in the ROM (not shown).

### <Configuration of Plasma Treatment Apparatus>

As the semiconductor manufacturing apparatus to which the chiller device 100 is applied, a plasma treatment apparatus 200 involving plasma treatment can be given.

As illustrated in FIG. 3, the plasma treatment apparatus 200 includes a vacuum container (chamber) 201. Inside the vacuum container (chamber) 201, there is provided an electrostatic chuck 136 (ESC) as one example of the temperature control target for holding the semiconductor wafer W being the temperature control target under a state of electrostatically attracting the semiconductor wafer W. The flow passage 135 for temperature control, through which the fluid 101 for temperature control flows from the chiller device 100, is continuously formed in the electrostatic chuck 136. Further, the plasma treatment apparatus 200 includes a lower electrode (cathode electrode) 202 and an upper electrode (anode electrode) 203. The lower electrode 202 is also used as the electrostatic chuck 136, and is coupled to a lid portion. The upper electrode 203 is arranged to be opposed to the lower electrode 202, and integrally includes the lid portion. The temperature control target may include not only the lower electrode (cathode electrode) 202 but also the upper electrode (anode electrode) 203.

Further, a gas intake port 201a is formed in the vacuum container 201, and is configured to introduce active gas (reactive gas) for etching therethrough. The upper electrode 203 is connected to a ground potential (GND) through intermediation of the lid portion extending outward. Further, the lower electrode 202 is connected to a radio-frequency (RF) oscillator 204 and a blocking capacitor 205 through intermediation of the lid portion extending outward. One end of the radio-frequency (RF) oscillator 204 is connected to the ground potential (GND). Moreover, a light emission detector 206 is provided on an outer side of a window portion formed in a wall of the vacuum container 201 opposed to the gas intake port 201a, and is configured to monitor a light emission state when plasma for etching is produced to perform etching by the plasma treatment.

The plasma used for etching of the semiconductor wafer W has a characteristic of reaching a high temperature within an extremely short period of time. The electrostatic chuck 136 that holds the semiconductor wafer W under a state of electrostatically attracting the semiconductor wafer W has a tendency to suddenly increase its temperature along with progress of the plasma treatment.

Under a state in which the active gas is ionized through the plasma treatment, positive ions of the active gas are attracted to the temperature control target W located on a side of the lower electrode 202 being the cathode electrode, and thus are used for etching. Electrons produced by ionizing the active gas through the plasma treatment exhibit various behaviors. The electrons flow toward the temperature control target W, or flow to the ground potential through the upper electrode 203. Most of the electrons are stored in the blocking capacitor 205 through the lower electrode 202.

As the temperature control target W to be controlled in temperature by the chiller device 100, a semiconductor element such as a three-dimensional NAND flash memory, a flat panel display (FPD), or a solar cell is given.

### <Basic Operation of Chiller Device>

The chiller device 100 basically operates as follows.

The chiller device 100 controls, for example, the temperature of the fluid 101 for temperature control to be supplied to the temperature adjustment target device 102 so that the temperature becomes equal to a predetermined temperature, for example, −30° C. Here, it is desired that the temperature of the fluid 101 for temperature control supplied by the fluid supply portion 104 be set to, for example, about −30° C., which is a predetermined temperature lower than 0° C., in consideration of an increase in temperature of the temperature adjustment control target along with the progress of the treatment. It is apparent that the temperature of the fluid 101 for temperature control is not limited to about −30° C. and may be higher or lower than about −30° C.

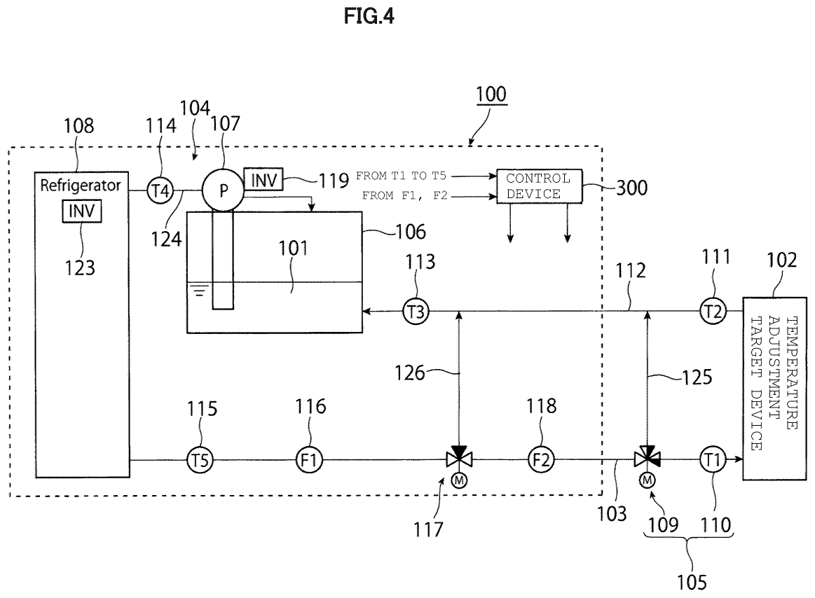

When the temperature of the temperature adjustment target device 102 is controlled to about −30° C., the chiller device 100 sets the opening degree of the first three-way valve 109 for flow rate control to, for example, 50%, as illustrated in FIG. 4, so that the amount of the fluid 101 for temperature control flowing into the temperature adjustment target device 102 via the supply pipe 103 and the amount of the fluid 101 for temperature control to be returned to the fluid supply portion 104 are controlled to be equal to each other.

Further, the chiller device 100 sets the opening degree of the second three-way valve 117 for flow rate control to, for example, 100% so as to cause all the fluid 101 for temperature control supplied from the refrigerator 108 into the first three-way valve 109 for flow rate control.

As a result, 50% of the fluid 101 for temperature control in the fluid 101 for temperature control adjusted to the predetermined temperature of −30° C. is supplied from the fluid supply portion 104 to the flow passage 135 for temperature control in the temperature adjustment target device 102. As a result, the temperature of the temperature adjustment target device 102 is controlled to be −30° C., which is the temperature of the fluid 101 for temperature control supplied from the fluid supply portion 104.

The control device 300 calculates the flow rate Q1 of the fluid 101 for temperature control to be supplied to the temperature adjustment target device 102 and a flow rate Q2 of the fluid 101 for temperature control returning toward the chiller device 100 in accordance with opening-degree information of the first three-way valve 109 for flow rate control based on the flow rate of the fluid 101 for temperature control supplied to the first three-way valve 109 for flow rate control, which has been detected by the second flow rate sensor 118.

Next, the control device 300 calculates the heat load H1 of the temperature adjustment target device 102 by the arithmetic expression (1) based on the flow rate Q1 of the fluid 101 for temperature control to be supplied to the temperature adjustment target device 102 and the results of detection performed by the first temperature sensor 110 and the second temperature sensor 111.

$$H 1 = m \cdot c \cdot Δ T \qquad ( 1 )$$

The control device 300 controls a frequency F1 that determines the rpm of the second inverter motor 123 of the refrigerator 108 by an arithmetic expression (2) based on the heat load H1 of the temperature adjustment target device 102, which has been detected by the detection means 105.

$$F 1 = {( ( H 1 - b ) / a )}^{0.5} \qquad ( 2 )$$

NOW, when an etching step involving the plasma treatment on the semiconductor wafer W is started in the plasma treatment apparatus 200 as the temperature adjustment target device 102, the fluid 101 for temperature control flows out from the electrostatic chuck 136 that holds the semiconductor wafer W under a state of electrostatically attracting the semiconductor wafer W and a temperature T2 of the fluid 101 for temperature control, which is detected by the second temperature sensor 111, suddenly increases as shown in FIG. 5.

Then, the control device 300 calculates the heat load H1 of the temperature adjustment target device 102 based on the expression (1) described above and performs control so as to immediately and suddenly increase, as shown in FIG. 5, the frequency F1 of the AC power, which determines the rpm of the second inverter motor 123 of the refrigerator 108 in response to the calculated suddenly increasing heat load H1.

Thus, when a sudden increase in the heat load H1 of the temperature adjustment target device 102 is detected by the first temperature sensor 110 and the second temperature sensor 111, the control device 300 can immediately and significantly increase the rpm of the second inverter motor 123 of the refrigerator 108 so as to increase the cooling performance.

As a result, after the fluid 101 for temperature control, which has a temperature suddenly increased as a result of the passage through the temperature adjustment target device 102, passes through the storage tank 106, the fluid 101 for temperature control is efficiently cooled by the refrigerator 108 having the cooling performance that has been increased in advance and is supplied as the fluid 101 for temperature control, which has a temperature substantially equal to the predetermined temperature of −30° C., to the temperature adjustment target device 102.

Simultaneously, the control device 300 controls the distribution ratio at the first three-way valve 109 for flow rate control as needed so as to increase the flow rate of the fluid 101 for temperature control to be supplied to the temperature adjustment target device 102.

As described above, the chiller device 100 according to the first embodiment can control with high accuracy the temperature of the fluid 101 for temperature control to be supplied to the temperature adjustment target device 102 in comparison to a case in which the control device 300 for controlling temperature adjustment performance (cooling performance) of the fluid supply portion 104 based on the result of detection performed by the detection means 105 for detecting the heat load of the temperature adjustment target device 102 is not provided.

### Comparative Example

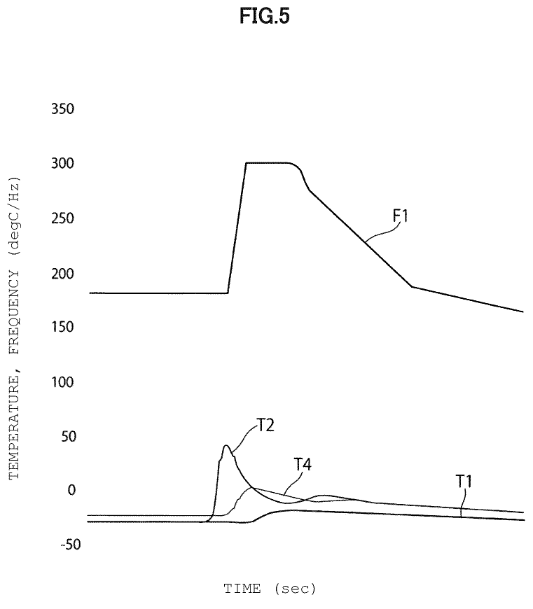

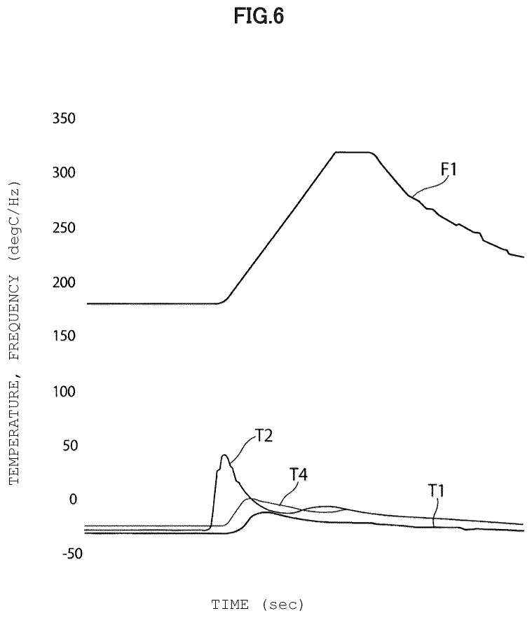

Meanwhile, in the related art, as shown in FIG. 6, the frequency F1 that determines the rpm of the second inverter motor 123 of the refrigerator 108 is controlled by proportional control after an increase in temperature T4 of the fluid 101 for temperature control is detected by the third temperature sensor 113 arranged on an upstream side of the storage tank 106. Thus, when the etching step involving the plasma treatment on the semiconductor wafer W is started in the plasma treatment apparatus 200, a temperature T1 of the fluid 101 for temperature control to be supplied to the temperature adjustment target device 102 is increased due to overshoot. As a result, the temperature of the workpiece W in the temperature adjustment target device 102 is increased, and processing accuracy is reduced or the like. Thus, it is difficult to control with high accuracy the temperature of the fluid 101 for temperature control to be supplied to the temperature adjustment target device 102.

### Second Embodiment

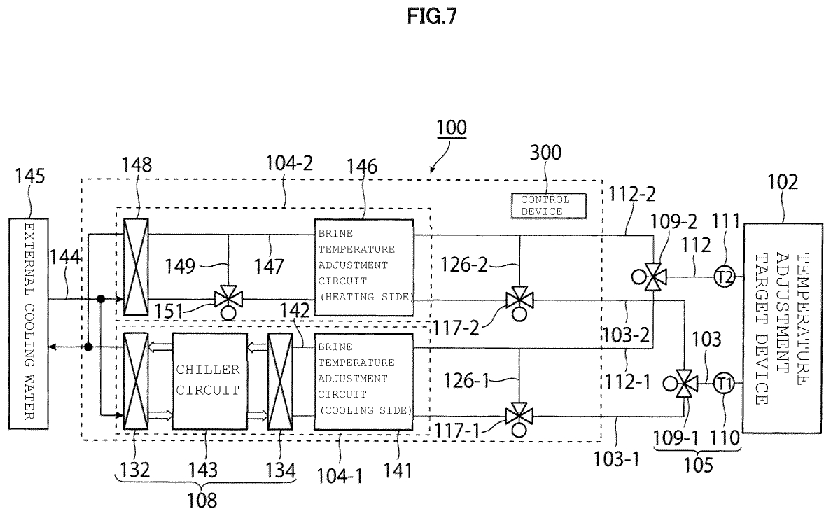

FIG. 7 is a schematic configuration diagram for illustrating a constant-temperature maintaining device (chiller device) as one example of a temperature control device according to a second embodiment of the present invention.

The chiller device 100 according to the first embodiment has been described only for a case in which the fluid for temperature control with only one temperature setting is used as the fluid 101 for temperature control. Meanwhile, a chiller device 100 according to the second embodiment is configured to use two kinds of fluids for temperature control, that is, a lower temperature fluid adjusted to a predetermined first temperature being a lower temperature and a higher temperature fluid adjusted to a predetermined second temperature being a higher temperature.

That is, as illustrated in FIG. 7, the chiller device 100 of the second embodiment includes a lower temperature fluid supply portion 104-1 and a higher temperature fluid supply portion 104-2. The lower temperature fluid supply portion 104-1 is one example of first supply means for supplying a lower temperature fluid adjusted to a predetermined constant lower temperature. The higher temperature fluid supply portion 104-2 is one example of second supply means for supplying a higher temperature fluid adjusted to a predetermined constant higher temperature. The lower temperature fluid 101-1 supplied from the lower temperature fluid supply portion 104-1 and the higher temperature fluid 101-2 supplied from the higher temperature fluid supply portion 104-2 are mixed under a state in which a mixture ratio between the lower temperature fluid 101-1 and the higher temperature fluid 101-2 is adjusted through a third three-way valve 109-1 for flow rate control to form a fluid for temperature control, and then the fluid for temperature control is fed through a supply pipe 103 to a temperature adjustment target device 102 being one example of temperature control target formed of, for example, an electrostatic chuck (ESC) configured to hold the temperature control target (workpiece) W.

The temperature adjustment target device 102 has a flow passage 135 for temperature control (see FIG. 3) therein. The fluid for temperature control, which is obtained by mixing the lower temperature fluid and the higher temperature fluid at a desired mixture ratio and adjusting the mixture to a desired temperature, flows through the flow passage 135 for temperature control. On an outflow side of the flow passage 135 for temperature control, a fourth three-way valve 109-2 for flow rate control is provided. The fourth three-way valve 109-2 for flow rate control is configured to distribute the fluid for temperature control, which has flowed through the flow passage 135 for temperature control, to the lower temperature fluid supply portion 104-1 and the higher temperature fluid supply portion 104-2 through a return pipe 112 at a desired ratio (distribution ratio).

The lower temperature fluid supply portion 104-1 includes a first bypass pipe 126-1. Of the lower temperature fluid supplied from the lower temperature fluid supply portion 104-1 to the third three-way valve 109-1 for flow rate control through a lower-temperature-side mixing pipe 103-1, a part of the lower temperature fluid prevented from being supplied to the third three-way valve 109-1 for flow rate control is returned to the lower temperature fluid supply portion 104-1 through the first bypass pipe 126-1. On a supply side of the lower temperature fluid supply portion 104-1, a fifth three-way valve 117-1 for flow rate control is provided. The fifth three-way valve 117-1 for flow rate control is configured to control a flow rate of the fluid for temperature control, which flows through the flow passage 135 for temperature control and is distributed by the fourth three-way valve 109-2 for flow rate control to the lower temperature fluid supply portion 104-1 through a lower-temperature-side distributing pipe 112-1, and a flow rate of the lower temperature fluid, which is prevented from being supplied from the lower temperature fluid supply portion 104-1 to the third three-way valve 109-1 for flow rate control and is returned to the lower temperature fluid supply portion 104-1 through the first bypass pipe 126-1.

Meanwhile, the higher temperature fluid supply portion 104-2 includes a fourth bypass pipe 126-2. Of the higher temperature fluid supplied from the higher temperature fluid supply portion 104-2 to the third three-way valve 109-1 for flow rate control through a higher-temperature-side mixing pipe 103-2, a part of the higher temperature fluid prevented from being supplied to the third three-way valve 109-1 for flow rate control is returned to the higher temperature fluid supply portion 104-2 through the fourth bypass pipe 126-2. On a supply side of the higher temperature fluid supply portion 104-2, a sixth three-way valve 117-2 for flow rate control is provided. The sixth three-way valve 117-2 for flow rate control is configured to control a flow rate of the fluid for temperature control, which flows through the flow passage 135 for temperature control and is distributed by the fourth three-way valve 109-2 for flow rate control to the higher temperature fluid supply portion 104-2 through a higher-temperature-side distributing pipe 112-2, and a flow rate of the higher temperature fluid, which is prevented from being supplied from the higher temperature fluid supply portion 104-2 to the fourth three-way valve 109-2 for flow rate control and is returned to the higher temperature fluid supply portion 104-2 through the second bypass pipe 126-2. As the lower temperature fluid and the higher temperature fluid, the same heating medium (brine) is used.

As illustrated in FIG. 7, the lower temperature fluid supply portion 104-1 includes a cooling-side brine temperature adjustment circuit 141 configured to adjust the brine to a predetermined constant lower temperature. A secondary side of an evaporator 134 is connected to the cooling-side brine temperature adjustment circuit 141 through intermediation of a lower-temperature-side circulating pipe 142. A chiller circuit 143 is connected to a primary side of the evaporator 134. The chiller circuit 143 is configured to cool the brine, which flows through the secondary side of the evaporator 134, to a desired temperature. The chiller circuit 143 cools the brine flowing through the secondary side of the evaporator 134 to the desired temperature by expanding the heating medium condensed by a condenser 132 and feeding the heating medium to the primary side of the evaporator 134. Further, the brine flowing through the chiller circuit 143 is condensed by the condenser 132. External cooling water 145 is supplied to the condenser 132 through a cooling water pipe 144.

Further, the higher temperature fluid supply portion 104-2 includes a heating-side brine temperature adjustment circuit 146 configured to adjust the brine to a predetermined constant higher temperature. The heating-side brine temperature adjustment circuit 146 has heating means such as a heater (not shown). A heat exchanger 148 is connected to the heating-side brine temperature adjustment circuit 146 through intermediation of a higher-temperature-side circulating pipe 147. A fifth bypass pipe 149 is connected between the heating-side brine temperature adjustment circuit 146 and the heat exchanger 148. The fifth bypass pipe 149 allows the heating medium flowing from the heating-side brine temperature adjustment circuit 146 to the heat exchanger 148 to flow to the heating-side brine temperature adjustment circuit 146. Further, on an inflow side of the fifth bypass pipe 149, a seventh three-way valve 151 for flow rate control is provided. The seventh three-way valve 151 for flow rate control is configured to control a flow rate of the fluid for temperature control supplied to the heat exchanger 148 and a flow rate of the fluid for temperature control caused to bypass the heat exchanger 148 and returned to the heating-side brine temperature adjustment circuit 146. The external cooling water 145 is supplied to the heat exchanger 148 through the cooling water pipe 144. The heat exchanger 148 cools the brine. For example, when a temperature of the higher temperature fluid flowing through the higher-temperature-side circulating pipe 147 is equal to or lower than a predetermined threshold value, the seventh three-way valve 151 for flow rate control adjusts an opening degree so as to return a part or entirety of the higher temperature fluid flowing through the higher-temperature-side circulating pipe 147 directly to the heating-side brine temperature adjustment circuit 146.

### <Basic Operation of Chiller Device>

The chiller device 100 basically operates as follows.

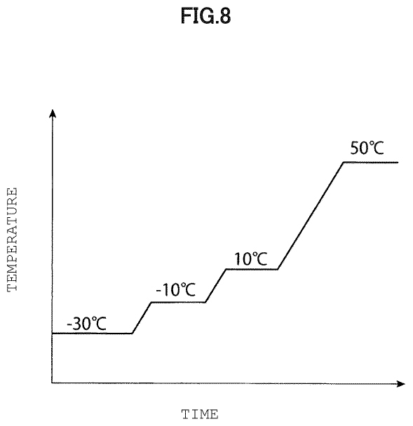

As illustrated in FIG. 8, the chiller device 100 controls a temperature of the fluid for temperature control to be supplied to the temperature adjustment target device 102 to, for example, −30° C., −10° C., 10° C., and 50° C. in the plurality of steps in a stepwise manner. Here, the temperature of the lower temperature fluid supplied from the lower temperature fluid supply portion 104-1 is set to, for example, −30° C., which is equal to the lowest temperature among control temperatures in the plurality of steps. Further, the temperature of the higher temperature fluid supplied from the higher temperature fluid supply portion 104-2 is set to, for example, about 50° C., which is equal to the highest temperature among the control temperatures in the plurality of steps. However, in the embodiment, the temperature of the lower temperature fluid and the temperature of the higher temperature fluid are not limited to the lowest temperature and the highest temperature among the control temperatures in the plurality of steps. As a matter of course, the temperature of the lower temperature fluid and the temperature of the higher temperature fluid may be set to freely selected temperatures, for example, a temperature lower than the lowest temperature or the highest temperature among the control temperatures in the plurality of steps.

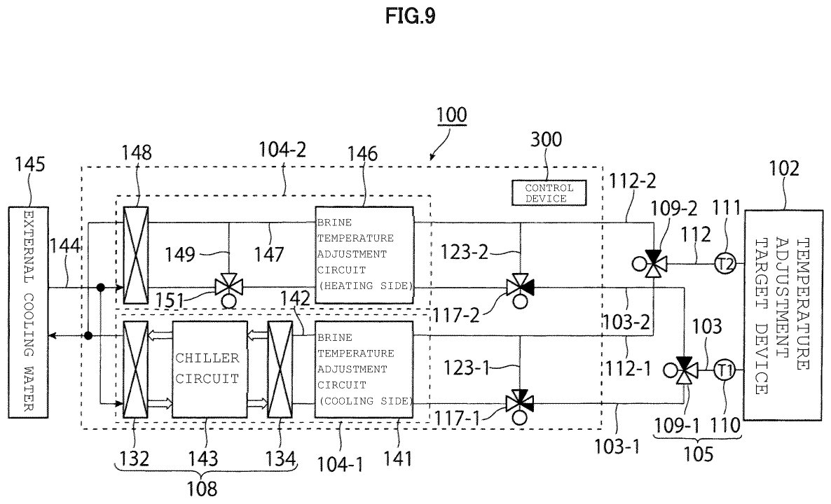

As illustrated in FIG. 9, when the chiller device 100 controls the temperature of the fluid for temperature control to −30° C., which is the lowest temperature among the control temperatures in the plurality of steps, the chiller device 100 interrupts the higher temperature fluid flowing into the third three-way valve 109-1 for flow rate control through the higher-temperature-side mixing pipe 103-2 so as to set the flow rate of the higher temperature fluid to zero, and releases the lower temperature fluid flowing into the third three-way valve 109-1 for flow rate control through the lower-temperature-side mixing pipe 103-1 so as to set the flow rate of the lower temperature fluid to 100%. Further, the chiller device 100 interrupts the higher temperature fluid distributed from the fourth three-way valve 109-2 for flow rate control to the higher temperature fluid supply portion 104-2 through the higher-temperature-side distributing pipe 112-2 so as to set the distribution amount of the higher temperature fluid to zero, and releases the lower temperature fluid distributed from the fourth three-way valve 109-2 for flow rate control to the lower temperature fluid supply portion 104-1 through the lower-temperature-side distributing pipe 112-1 so as to set the distribution amount of the lower temperature fluid to 100%. Along with this, the chiller device 100 releases the higher temperature fluid returned by the sixth three-way valve 117-2 for flow rate control to the higher temperature fluid supply portion 104-2 through the second bypass pipe 123-2, and returns all the higher temperature fluid supplied from the higher temperature fluid supply portion 104-2 to the higher temperature fluid supply portion 104-2. Further, the chiller device 100 sets the flow rate of the lower temperature fluid returned by the fifth three-way valve 117-1 for flow rate control to the lower temperature fluid supply portion 104-1 through the first bypass pipe 123-1 to 50%, and supplies the 50% of the flow rate of the lower temperature fluid supplied from the lower temperature fluid supply portion 104-1 to the third three-way valve 109-1 for flow rate control.

As a result, the fluid for temperature control adjusted in temperature to −30° C. is supplied from the lower temperature fluid supply portion 104-1 to the flow passage 135 for temperature control of the temperature adjustment target device 102, and the temperature of the temperature adjustment target device 102 is controlled to −30° C., which is the temperature of the fluid for temperature control including only the lower temperature fluid.

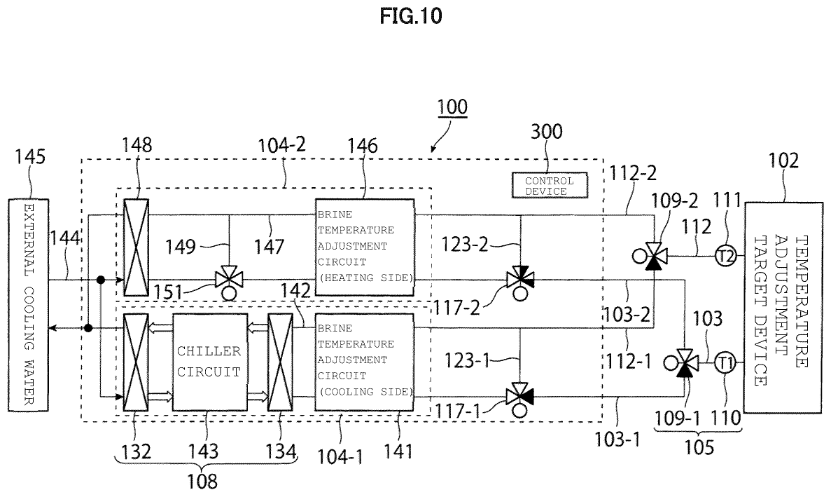

Further, as illustrated in FIG. 10, when the chiller device 100 controls the temperature of the fluid for temperature control to 50° C., which is the highest temperature among the control temperatures in the plurality of steps, the chiller device 100 releases the higher temperature fluid flowing into the third three-way valve 109-1 for flow rate control through the higher-temperature-side mixing pipe 103-1 so as to set the flow rate of the higher temperature fluid to 100%, and interrupts the lower temperature fluid flowing into the third three-way valve 109-1 for flow rate control through the lower-temperature-side mixing pipe 103-2 so as to set the flow rate of the lower temperature fluid to zero. Further, the chiller device 100 releases the higher temperature fluid distributed from the fourth three-way valve 109-2 for flow rate control to the higher temperature fluid supply portion 104-2 through the higher-temperature-side distributing pipe 112-2 so as to set the distribution amount of the higher temperature fluid to 100%, and interrupts the lower temperature fluid distributed from the fourth three-way valve 109-2 for flow rate control to the lower-temperature fluid supply portion 104-1 through the lower-temperature-side distributing pipe 112-1 so as to set the distribution amount of the lower temperature fluid to zero. Along with this, the chiller device 100 interrupts the higher temperature fluid returned by the fourth three-way valve 109-2 for flow rate control to the higher temperature fluid supply portion 104-2 through the second bypass pipe 123-2, and supplies all the higher temperature fluid supplied from the higher temperature fluid supply portion 104-2 to the third three-way valve 109-1 for flow rate control. Further, the chiller device 100 releases the lower temperature fluid returned by the fifth three-way valve 117-1 for flow rate control to the lower temperature fluid supply portion 104-1 through the first bypass pipe 123-1, and returns all the lower temperature fluid supplied from the lower temperature fluid supply portion 104-1 to the lower temperature fluid supply portion 104-1. Further, the chiller device 100 sets the flow rate of the lower temperature fluid returned by the sixth three-way valve 117-2 for flow rate control to the higher temperature fluid supply portion 104-2 through the second bypass pipe 123-2 to 50%, and returns 50% of the higher temperature fluid supplied from the higher temperature fluid supply portion 104-2 to the higher temperature fluid supply portion 104-2.

As a result, the fluid for temperature control adjusted in temperature to 50° C. is supplied from the higher temperature fluid supply portion 104-2 to the flow passage 135 for temperature control of the temperature adjustment target device 102, and the temperature of the temperature adjustment target device 102 is controlled to 50° C., which is the temperature of the fluid for temperature control including only the higher temperature fluid.

Moreover, as illustrated in FIG. 8, when the chiller device 100 controls the temperature of the fluid for temperature control to −10° C. or 10° C. being an intermediate temperature among the control temperatures in the plurality of steps, the chiller device 100 adjusts the opening degree of the third three-way valve 109-1 for flow rate control in accordance with the intermediate temperature being a target temperature for the temperature adjustment target device 102, and controls, to a desired value, the mixture ratio between the lower temperature fluid supplied from the lower temperature fluid supply portion 104-1 through the lower-temperature-side mixing pipe 103-1 and the higher temperature fluid supplied from the higher temperature fluid supply portion 104-2 through the higher-temperature-side mixing pipe 103-2. From the chiller device 100, the fluid for temperature control, which includes the lower temperature fluid and the higher temperature fluid mixed together in accordance with the opening degree of the third three-way valve 109-1 for flow rate control, is supplied to the flow passage 135 for temperature control of the temperature adjustment target device 102. Further, the chiller device 100 adjusts the opening degree of the fourth three-way valve 109-2 for flow rate control, and controls the distribution ratio between the lower temperature fluid and the higher temperature fluid distributed to the lower temperature fluid supply portion 104-1 and the higher temperature fluid supply portion 104-2 in accordance with the mixture ratio between the lower temperature fluid and the higher temperature fluid mixed together in the third three-way valve 109-1 for flow rate control.

For example, when the mixture ratio between the lower temperature fluid and the higher temperature fluid in the third three-way valve 109-1 for flow rate control is 4:6, the opening degree of the fourth three-way valve 109-2 for flow rate control is controlled so that the same distribution ratio of 4:6 is obtained between the lower temperature fluid and the higher temperature fluid, and the fourth three-way valve 109-2 for flow rate control distributes the fluid for temperature control with such ratio to the lower temperature fluid supply portion 104-1 and the higher temperature fluid supply portion 104-2.

Along with this, the chiller device 100 controls the flow rate of the higher temperature fluid returned by the sixth three-way valve 117-2 for flow rate control to the higher temperature fluid supply portion 104-2 through the second bypass pipe 123-2, and thus returns the remaining higher temperature fluid, which is supplied from the higher temperature fluid supply portion 104-2 to the third three-way valve 109-1 for flow rate control, to the higher temperature fluid supply portion 104-2. Similarly, the chiller device 100 controls the flow rate of the lower temperature fluid returned by the fifth three-way valve 117-1 for flow rate control to the lower temperature fluid supply portion 104-1 through the first bypass pipe 123-1, and thus returns the remaining lower temperature fluid, which is supplied from the lower temperature fluid supply portion 104-1 to the third three-way valve 109-1 for flow rate control, to the lower temperature fluid supply portion 104-1.

In the above-mentioned example, for example, when the mixture ratio between the lower temperature fluid and the higher temperature fluid in the third three-way valve 109-1 for flow rate control is 4:6, the sixth three-way valve 117-2 for flow rate control controls a ratio (flow rate ratio) between the higher temperature fluid returned to the higher temperature fluid supply portion 104-2 through the second bypass pipe 123-2 and the fluid for temperature control distributed by the fourth three-way valve 109-2 for flow rate control to the higher temperature fluid supply portion 104-2 to 4:6.

Similarly, in the above-mentioned example, for example, when the mixture ratio between the lower temperature fluid and the higher temperature fluid in the third three-way valve 109-1 for flow rate control is 4:6, the fifth three-way valve 117-1 for flow rate control controls a ratio (flow rate ratio) between the lower temperature fluid returned to the lower temperature fluid supply portion 104-1 through the first bypass pipe 123-1 and the fluid for temperature control distributed by the fourth three-way valve 109-2 for flow rate control to the lower temperature fluid supply portion 104-1 to 6:4.

As a result, the fluid for temperature control, which is obtained by mixing the lower temperature fluid supplied from the lower temperature fluid supply portion 104-1 and the higher temperature fluid supplied from the higher temperature fluid supply portion 104-2 in accordance with the opening degree of the third three-way valve 109-1 for flow rate control, is supplied to the flow passage 135 for temperature control of the temperature adjustment target device 102. Thus, a temperature of the temperature adjustment target device 102 is controlled to be equal to the temperature of the fluid for temperature control determined in accordance with the mixture ratio between the lower temperature fluid and the higher temperature fluid.

At this time, a control device 300 calculates a heat load H2 of the temperature adjustment target device 102 by an arithmetic expression (3) based on flow rates Q of the fluids 101-1 and 101-2 for temperature control supplied to the temperature adjustment target device 102 via the third three-way valve 109-1 for flow rate control and the fourth three-way valve 109-2 for flow rate control and the results of detection performed by a first temperature sensor 110 and a second temperature sensor 111.

$$H 2 = ( m 1 + m 2 ) \cdot c \cdot Δ t \qquad ( 3 )$$

Here, as shown in FIG. 11, each of the third three-way valve 109-1 for flow rate control and the fourth three-way valve 109-2 for flow rate control has a fluid distribution ratio with a substantially linear characteristic. Thus, for flow rates Qm of the fluids 101-1 and 101-2 for temperature control, when an opening degree of the third three-way valve 109-1 for flow rate control is set to x (1≥x≥0), a flow rate of one of the fluids is Qmx and a flow rate of another one of the fluids is Qm(1−x). The letter “m” is 1 or 2.

The control device 300 controls a frequency F2 that determines the rpm of the second inverter motor 123 of the refrigerator 108 by an arithmetic expression (4) based on the heat load H1 of the temperature adjustment target device 102, which has been detected by the detection means 105.

$$F 2 = {( ( H 2 - b ) / a )}^{0.5} \qquad ( 4 )$$

### <Configurations of First to Seventh Three-Way Valves for Flow Rate Control>

As described above, the chiller device 100 includes the first to seventh three-way valves 109, 1117, 109-1, 109-2, 117-1, 117-2, and 151 for flow rate control. The first to seventh three-way valves 109, 1117, 109-1, 109-2, 117-1, 117-2, and 151 for flow rate control basically have the same configuration except that a relationship between an inflow port and an outflow port is reversed depending on arrangement. Here, the three-way motor valve to be used as the first three-way valve 109 for flow rate control as distribution means is described as a representative.

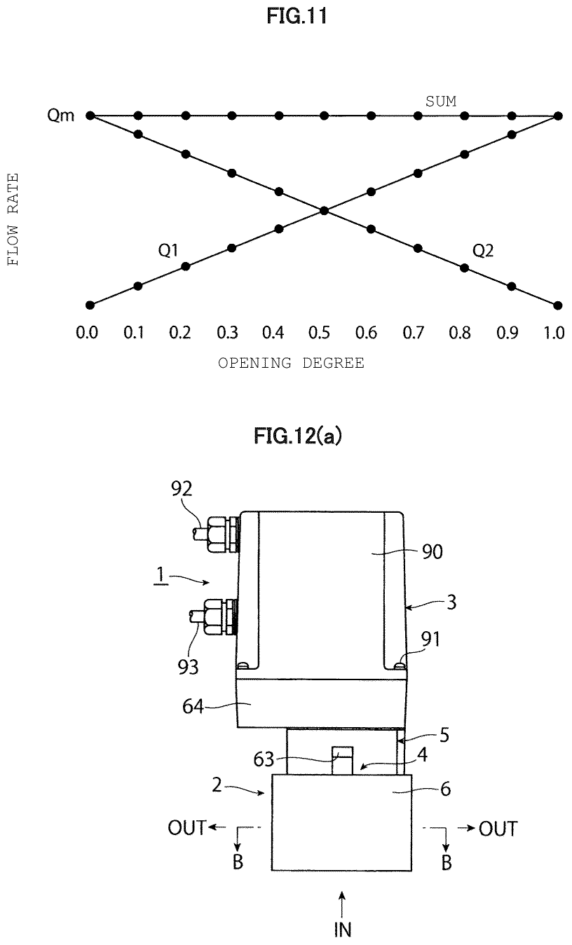

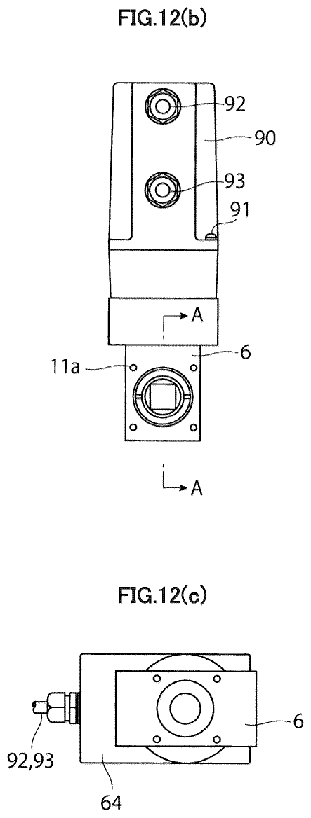

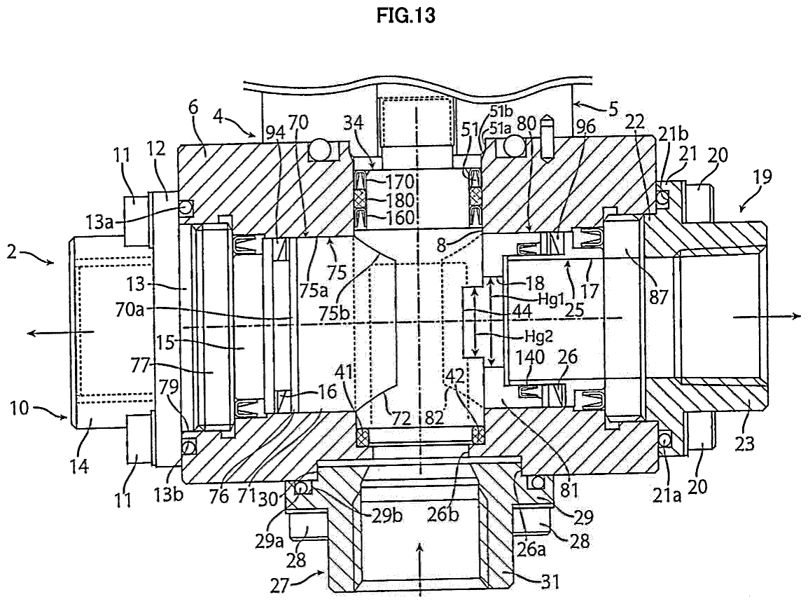

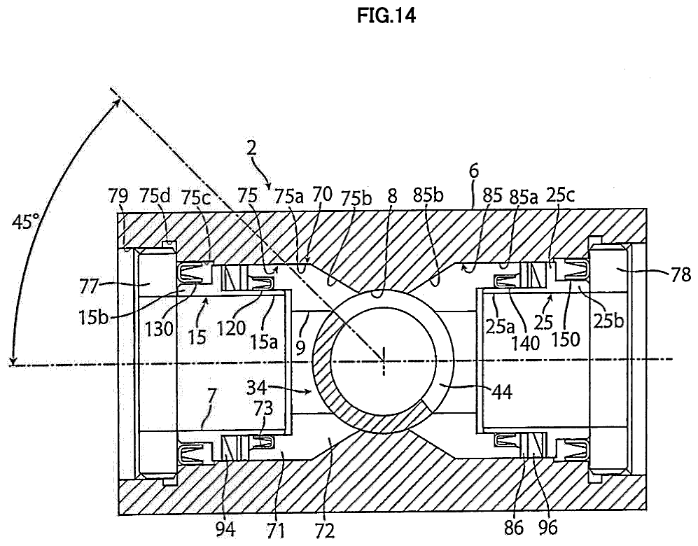

FIG. 12(a), FIG. 12(b), and FIG. 12(c) are a front view, a left side view, and a bottom view for illustrating a three-way motor valve as one example of the three-way valve for flow rate control according to the first embodiment of the present invention. FIG. 13 is a sectional view taken along the line A-A of FIG. 12(b), FIG. 14 is a sectional view taken along the line B-B of FIG. 12(a), and FIG. 15 is a sectional perspective view for illustrating relevant parts of the three-way motor valve.

A three-way motor valve 1 is constructed as a rotary three-way valve. As illustrated in FIG. 12, the three-way motor valve 1 mainly includes a valve portion 2 arranged at a lower portion thereof, an actuator 3 arranged at an upper portion thereof, and a sealing portion 4 and a coupling portion 5, which are arranged between the valve portion 2 and the actuator 3.

As illustrated in FIG. 13 to FIG. 15, the valve portion 2 includes a valve main body 6 obtained by forming metal, for example, SUS, into a substantially rectangular parallelepiped shape. As illustrated in FIG. 13 and FIG. 14, a first outflow port 7 and a first valve port 9 are formed in one side surface (left side surface in the illustrated example) of the valve main body 6. The first outflow port 7 allows outflow of a fluid. The first valve port 9 as one example of a communication port has a rectangular cross section, and communicates with a valve seat 8 having a columnar space.

In the first embodiment, instead of directly forming the first outflow port 7 and the first valve port 9 in the valve main body 6, a first valve seat 70 as one example of a first valve port forming member having the first valve port 9, and a first flow passage forming member 15 forming the first outflow port 7 are fitted to the valve main body 6, thereby providing the first outflow port 7 and the first valve port 9.

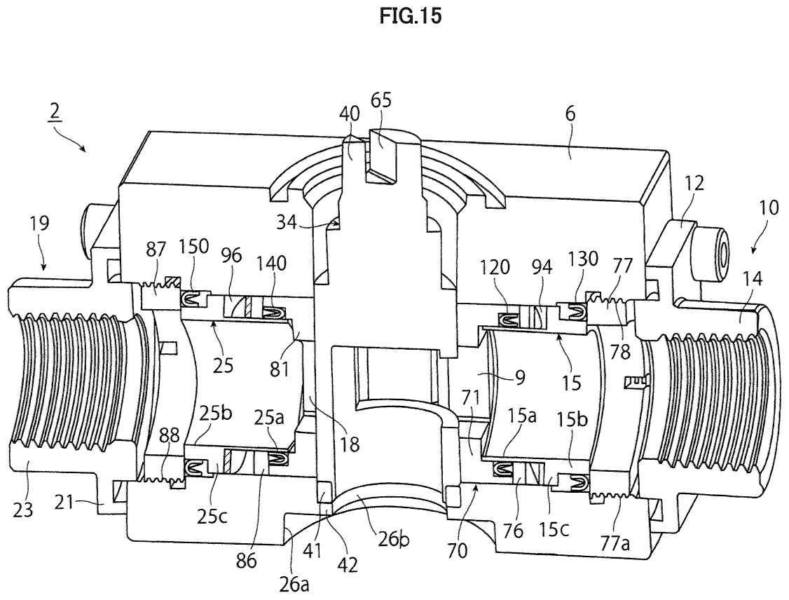

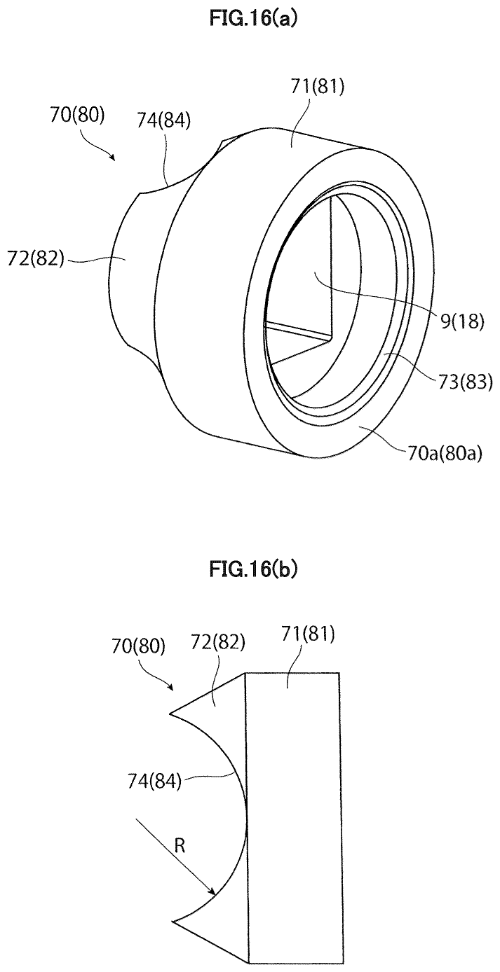

As illustrated in FIGS. 16, the first valve seat 70 integrally includes a cylindrical portion 71 and a tapered portion 72. The cylindrical portion 71 has a cylindrical shape and is provided outside the valve main body 6. The tapered portion 72 has a tapered shape with a distal end having an outer diameter decreasing toward an inner side of the valve main body 6. The first valve port 9 is formed in the tapered portion 72 of the first valve seat 70, and has a rectangular prism shape having a rectangular cross section (square cross section in the first embodiment). Further, as described later, one end portion of the first flow passage forming member 15 forming the first outflow port 7 is inserted in a hermetically sealed state (sealed state) into the cylindrical portion 71 of the first valve seat 70.

As a material for the first valve seat 70, for example, a polyimide (PI) resin is used. Further, as a material for the first valve seat 70, for example, so-called “super engineering plastic” can be used. The super engineering plastic has higher heat resistance and higher mechanical strength under a high temperature than ordinary engineering plastic. Examples of the super engineering plastic include, for example, polyether ether ketone (PEEK), polyphenylene sulfide (PPS), polyether sulfone (PES), polyamide imide (PAI), a liquid crystal polymer (LCP), polytetrafluoroethylene (PTFE), polychlorotrifluoroethylene (PCTFE), polyvinylidene fluoride (PVDF), or composite materials thereof. Further, as the material for the first valve sheet 70, there may be used, for example, “TECAPEEK” (trademark) manufactured by Ensinger Japan Co., Ltd. serving as a PEEK resin material for cutting work, and “TECAPEEK TF 10 blue” (product name) having blending therein 10% PTFE, which is excellent in sliding property, can also be used.

As illustrated in FIG. 14 and FIG. 15, a recess 75 is formed in the valve main body 6 by, for example, machining. The recess 75 has a shape corresponding to an outer shape of the first valve seat 70 and similar to the shape of the valve seat 70. The recess 75 includes a cylindrical portion 75a corresponding to the cylindrical portion 71 of the first valve seat 70 and a tapered portion 75b corresponding to the tapered portion 72. A length of the cylindrical portion 75a of the valve main body 6 is set larger than a length of the cylindrical portion 71 of the first valve seat 70. As described later, the cylindrical portion 75a of the valve main body 6 forms a part of a first pressure applying portion 94. The first valve seat 70 is fitted to the recess 75 of the valve main body 6 so as to be movable in a direction of moving close to and away from a valve shaft 34 serving as a valve body.

Under a state in which the first valve seat 70 is fitted to the recess 75 of the valve main body 6, a slight gap is defined between an outer peripheral surface of the first valve seat 70 and the inner peripheral surface of the recess 75 of the valve main body 6. A fluid having flowed into the valve seat 8 may leak and flow into a region around an outer periphery of the first valve seat 70 through the slight gap. Further, the fluid having leaked into the region around the outer periphery of the first valve seat 70 is led into the first pressure applying portion 94 being a space defined on an outer side of the cylindrical portion 71 of the first valve seat 70. The first pressure applying portion 94 is configured to apply a pressure of the fluid to a surface 70a of the first valve seat 70 opposite to the valve shaft 34. As described later, the fluid flowing into the valve seat 8 is a fluid flowing out through a second valve port 18 as well as a fluid flowing out through the first valve port 9. The first pressure applying portion 94 is partitioned under a state in which the first flow passage forming member 15 hermetically seals the first pressure applying portion 94 with respect to the first outflow port 7.

The pressure of the fluid, which is to be applied to the valve shaft 34 arranged inside the valve seat 8, depends on a flow rate of the fluid determined by an opening/closing degree of the valve shaft 34. The fluid flowing into the valve seat 8 also flows (leaks) through the first valve port 9 and the second valve port 18 into a slight gap defined between the valve seat 8 and an outer peripheral surface of the valve shaft 34. Therefore, into the first pressure applying portion 94 adapted for the first valve seat 70, not only the fluid flowing out through the first valve port 9 flows (leaks), but also the fluid flowing out the slight gap defined between the valve seat 8 and the outer peripheral surface of the valve shaft 34 and flowing in through the second valve port 18 flows (leaks).

As illustrated in FIG. 16(b), a concave portion 74 is formed at a distal end of the tapered portion 72 of the first valve seat 70. The concave portion 74 is one example of a gap reducing portion having an arc shape in plan view, which forms part of a curved surface of a columnar shape corresponding to the valve seat 8 having a columnar shape in the valve main body 6. A curvature radius R of the concave portion 74 is set to a value substantially equal to a curvature radius of the valve seat 8 or a curvature radius of the valve shaft 34. In order to prevent biting of the valve shaft 34 to be rotated inside the valve seat 8, the valve seat 8 of the valve main body 6 defines a slight gap with respect to the outer peripheral surface of the valve shaft 34. As illustrated in FIG. 17, the concave portion 74 of the first valve seat 70 is fitted so as to protrude toward the valve shaft 34 side more than the valve seat 8 of the valve main body 6 or so as to be brought into contact with the outer peripheral surface of the valve shaft 34 under a state in which the first valve seat 70 is fitted to the valve main body 6. As a result, a gap G between the valve shaft 34 and an inner surface of the valve seat 8 of the valve main body 6 being a member opposed to the valve shaft 34 is partially set to a value reduced by the protruding amount of the concave portion 74 of the first valve seat 70 as compared to that of a gap between the valve shaft 34 and another portion of the valve seat 8. Thus, a gap G1 between the concave portion 74 of the first valve seat 70 and the valve shaft 34 is set to a desired value (G1<G2) smaller than (or a gap narrower than) a gap G2 between the valve shaft 34 and the inner surface of the valve seat 8. The gap G1 between the concave portion 74 of the first valve seat 70 and the valve shaft 34 may correspond to a state in which the concave portion 74 of the first valve seat 70 is brought into contact with the valve shaft 34, that is, a state in which no gap is defined (the gap G1=0).

However, in a case in which the concave portion 74 of the first valve seat 70 is brought into contact with the valve shaft 34, there is a fear in that driving torque of the valve shaft 34 is increased due to contact resistance of the concave portion 74 when the valve shaft 34 is driven to rotate. Accordingly, a contact degree of the concave portion 74 of the first valve seat 70 with the valve shaft 34 is adjusted in consideration of rotational torque of the valve shaft 34. That is, the contact degree is adjusted to such an extent as to involve no increase in the driving torque of the valve shaft 34 or involve slight increase even when the driving torque is increased, and cause no trouble for rotation of the valve shaft 34.

As illustrated in FIG. 14 and FIG. 15, the first flow passage forming member 15 is made of metal such as SUS or a synthetic resin such as a polyimide (PI) resin, and has a cylindrical shape. The first flow passage forming member 15 has the first outflow port 7 formed therein to communicate with the first valve port 9 irrespective of shift of a position of the first valve seat 70. About half of the first flow passage forming member 15, which is positioned on the first valve seat 70 side, is formed as a small-thickness cylindrical portion 15a having a cylindrical shape with a relatively small thickness. Further, about half of the first flow passage forming member 15, which is positioned on a side opposite to the first valve seat 70, is formed as a large-thickness cylindrical portion 15b having a cylindrical shape with a larger thickness than a thickness of the cylindrical portion with a small thickness. An inner surface of the first flow passage forming member 15 has a cylindrical shape and penetrates the first flow passage forming member 15. A flange portion 15c having an annular shape is formed between the small-thickness cylindrical portion 15a and the large-thickness cylindrical portion 15b on an outer periphery of the first flow passage forming member 15. The flange portion 15c has a relatively large thickness and extends radially outward. An outer peripheral end of the flange portion 15c is arranged in contact with an inner peripheral surface of the recess 75 so as to be movable therealong.

As illustrated in FIG. 15, a gap between the cylindrical portion 71 of the first valve seat 70 and the small-thickness cylindrical portion 15a of the first flow passage forming member 15 is hermetically sealed (sealed) by an spring energized seal 120, which is one example of first sealing means. The spring energized seal 120 is made of a synthetic resin, has a substantially U-shaped cross section, and is urged in an opening direction by a spring member made of metal. As illustrated in FIGS. 16, a stepped portion 73 for receiving the spring energized seal 120 therein is formed in an end portion of an inner peripheral surface of the cylindrical portion 71 of the first valve seat 70, which is positioned on an outer side of the valve main body 6.

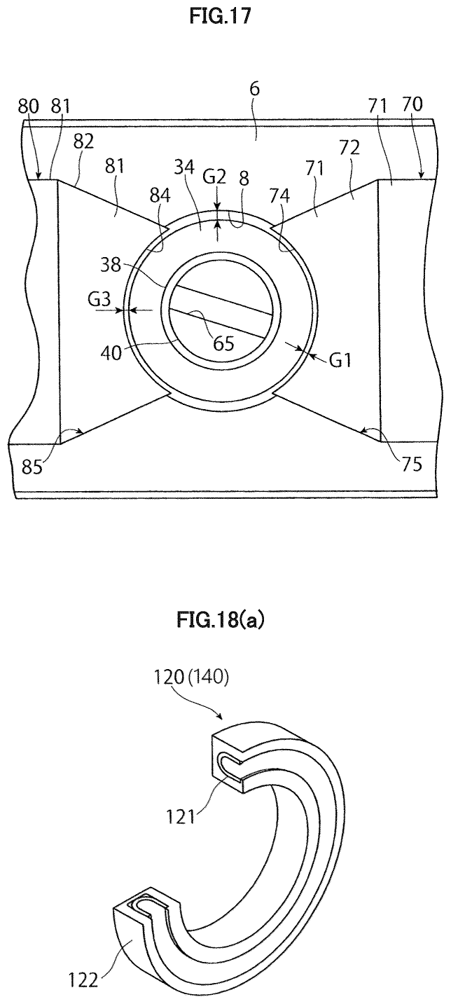

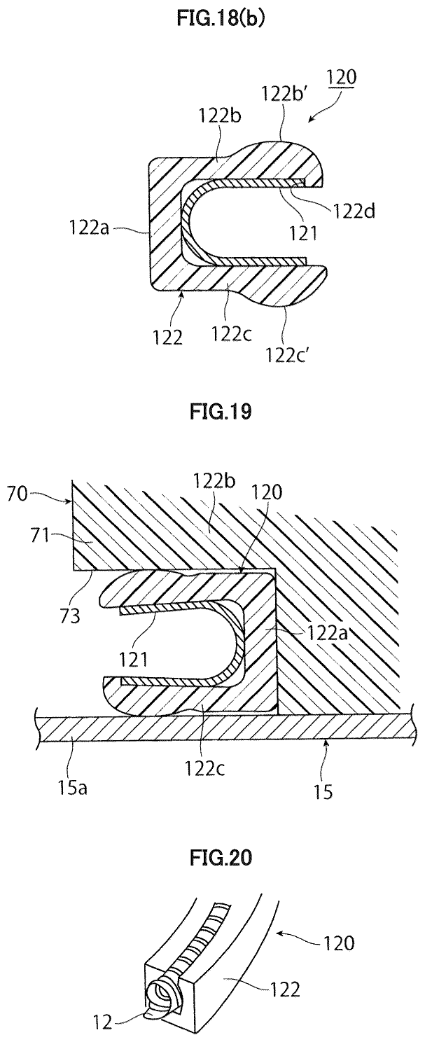

As illustrated in FIGS. 18, the spring energized seal 120 is an annular (ring-shaped) member arranged on the inner peripheral surface of the cylindrical portion 71 of the first valve seat 70 so as to extend along its entire periphery. The spring energized seal 120 includes a spring member 121 and a sealing member 122. The spring member 121 is made of metal such as stainless steel and has a substantially U-shaped cross section. The sealing member 122 is made of a synthetic resin such as polytetrafluoroethylene (PTFE), has a substantially U-shaped cross section, and is urged in an opening direction by the spring member 121. The spring member 121 is made of metal such as stainless steel, and has a substantially U-shaped cross section. An elastic modulus of the spring member 121 is adjusted by forming slits or grooves at constant intervals in a longitudinal direction or appropriately setting a thickness thereof. As illustrated in FIG. 18 and FIG. 19, the sealing member 122 includes a proximal end portion 122a and two lip portions 122b and 122c. The proximal end portion 122a is arranged in a sealing direction so as to be positioned in a space to be sealed between the stepped portion 73 formed in the cylindrical portion 71 of the first valve seat 70 and the small-thickness cylindrical portion 15a of the first flow passage forming member 15. The lip portions 122b and 122c extend from both ends of the proximal end portion 122a in the same direction (outward in an axial direction of the first valve seat 70) along peripheral surfaces of the two members to be sealed, and are arranged in parallel so as to be opposed to each other. Distal ends of the two lip portions 122b and 122c define a space opened outward in the axial direction of the first valve seat 70. An opening of the spring energized seal 120 is opened toward the first pressure applying portion 94 and receives a pressure applied by the first pressure applying portion 94. As illustrated in FIG. 18(b), a protruding portion 122d is formed on a distal end of one lip portion 122b. The protruding portion 122d protrudes inward with a thickness corresponding to the thickness of the spring member 121, and prevents the spring member 121 from being released therefrom. A distal end portion 122b′ of the lip portion 122b and a distal end portion 122c′ of the lip portion 122c each have a curved arc-like shape with an outer peripheral surface that starts protruding outward in its middle toward its distal end. The distal end portion 122b′ of the lip portion 122b and the distal end portion 122c′ of the lip portion 122c are in close contact with an inner peripheral surface of the first valve seat 70 and an outer peripheral surface of the first flow passage forming member 15 to thereby increase a degree of hermetical sealing.

The spring member 121 of the spring energized seal 120 is not limited to a spring member having a substantially U-shaped cross section. The spring member 121 may be, as illustrated in FIG. 20, a spring member obtained by forming a band-shaped metal into a helical shape with a circular cross section or an elliptical cross section.

When the pressure of the fluid is not applied to the spring energized seal 120 or the pressure of the fluid is relatively low, the spring energized seal 120 hermetically seals the gap between the first valve seat 70 and the first flow passage forming member 15 with an elastic restoration force of the spring member 121. Meanwhile, when the pressure of the fluid is relatively high, the spring energized seal 120 hermetically seals the gap between the first valve seat 70 and the first flow passage forming member 15 with the elastic restoration force of the spring member 121 and the pressure of the fluid. Thus, even when the fluid flows into the first pressure applying portion 94 through the gap between the inner peripheral surface of the valve main body 6 and the outer peripheral surface of the first valve seat 70, the gap between the first valve seat 70 and the first flow passage forming member 15 is sealed by the spring energized seal 120 and thus the fluid does not flow into the first flow passage forming member 15.

The spring energized seal 120 includes a combination of the spring member 121 made of metal and the sealing member 122 made of a synthetic resin. Not only the spring member 121 made of metal but also polytetrafluoroethylene (PTFE), which is a synthetic resin for forming the sealing member 122, is excellent in heat resistance. Polytetrafluoroethylene can withstand long time of use at temperatures of about −85° C. as a lowest temperature and about 260° C. as a highest temperature.

As illustrated in FIG. 13 and FIG. 14, the end surface 70a of the cylindrical portion 71 of the first valve seat 70 is a region (pressure-receiving surface) that receives the pressure of the fluid applied by the first pressure applying portion 94.

In the first embodiment, the stepped portion 73 for allowing the spring energized seal 120 to be mounted therein is formed in the end surface 70a of the cylindrical portion 71 of the first valve seat 70. Thus, the end surface 70a of the cylindrical portion 71 of the first valve seat 70 has a structure that is less liable to receive all the pressure of the fluid applied by the first pressure applying portion 94 because of the presence of the stepped portion 73.

Thus, in the first embodiment, as illustrated in FIG. 13 and FIG. 14, a first pressure-receiving plate 76 having an annular shape is provided so that the pressure of the fluid is effectively applied to the end surface 70a of the cylindrical portion 71 of the first valve seat 70 by the first pressure applying portion 94. The first pressure-receiving plate 76 covers the end surface 70a of the cylindrical portion 71 of the first valve seat 70, which includes the stepped portion 73 of the first valve seat 70, to achieve closure. Specifically, the first pressure-receiving plate 76 is arranged in contact with the end surface 70a of the cylindrical portion 71 of the first valve seat 70 so as to close the stepped portion 73. The first pressure-receiving plate 76 is made of the same material as that of the valve seat 70. Further, a slight gap is set between an outer peripheral end surface of the first pressure-receiving plate 76 in its radial direction and the recess 75 of the valve main body 6 so as to allow the fluid to leak into the first pressure applying portion 94.

Meanwhile, a gap between an end portion of the large-thickness cylindrical portion 15b, which is another end portion of the first flow passage forming member 15, and the inner peripheral surface of the valve main body 6 is hermetically sealed (sealed) by a second spring energized seal 130. The second spring energized seal 130 is one example of second sealing means that is made of a synthetic resin, has a substantially U-shaped cross section, and is urged in an opening direction by a spring member made of metal. As illustrated in FIGS. 16, a cylindrical portion 75c that allows the spring energized seal 130 to be mounted therein is formed on the inner peripheral surface of the valve main body 6. The cylindrical portion 75c having a short length is formed at an outer end portion of the cylindrical portion 75a of the recess 75 in the axial direction, and has an outer diameter slightly larger than that of the cylindrical portion 75a of the recess 75. The length of the cylindrical portion 75c is set longer than a length of the second spring energized seal 130.

A gap between the cylindrical portion 75c of the valve main body 6 and the large-thickness cylindrical portion 15b of the first flow passage forming member 15 is hermetically sealed (sealed) by the second spring energized seal 130. The second spring energized seal 130 is opened toward the first pressure applying portion 94. Specifically, the second spring energized seal 130 is arranged so that its opening receives the pressure of the fluid applied by the first pressure applying portion 94. Although the second spring energized seal 130 has the outer diameter larger than that of the first spring energized seal 120, the second spring energized seal 130 is basically constructed in the same manner as the first spring energized seal 120.

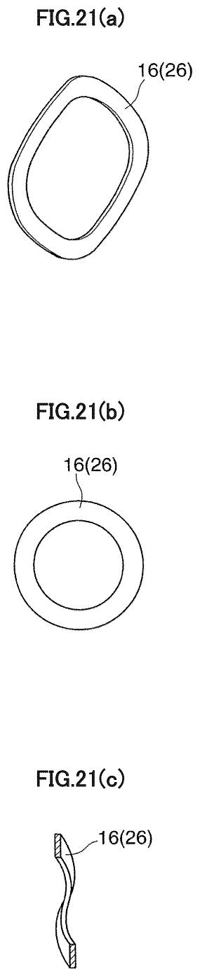

A first wave washer (corrugated washer) 16 is provided on an outer side of the cylindrical portion 71 of the first valve seat 70 along an axial direction thereof. The first wave washer 16 is one example of an elastic member configured to elastically deform the first valve seat 70 to move in the direction of moving close to and away from the valve shaft 34 while allowing displacement of the first valve seat 70 in the direction of moving close to and away from the valve shaft 34. As illustrated in FIGS. 21, the first wave washer 16 is made of, for example, stainless steel, iron, or phosphor bronze, and has an annular shape having a desired width when a front side thereof is projected. Further, a side surface of the first wave washer 16 is formed into a wavy (corrugated) shape, and the first wave washer 16 is elastically deformable in a thickness direction thereof. An elastic modulus of the first wave washer 16 is determined by, for example, the thickness, a material, or the number of waves of the first wave washer 16. The first wave washer 16 is received in the first pressure applying portion 94.

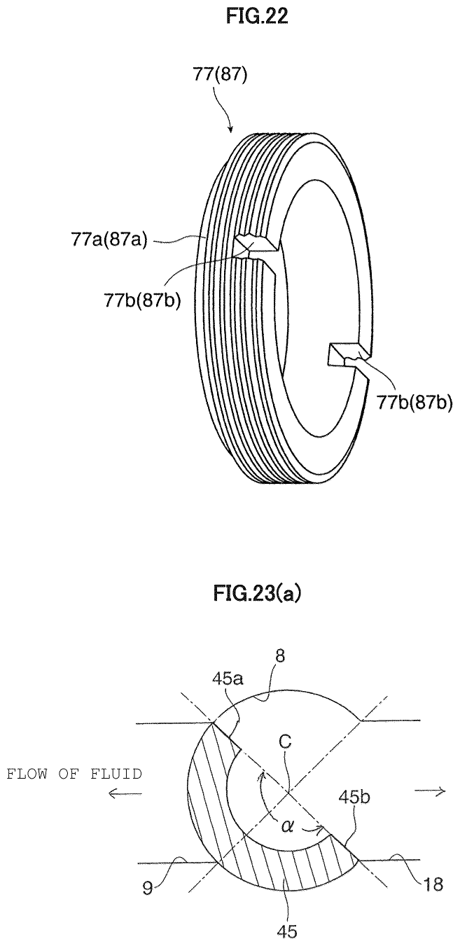

Moreover, a first adjusting ring 77 is arranged on an outer side of the first wave washer 16. The first adjusting ring 77 is one example of an annular adjusting member configured to adjust the gap G1 between the valve shaft 34 and the concave portion 74 of the first valve seat 70 via the first wave washer 16. As illustrated in FIG. 22, the first adjusting ring 77 is made of metal such as SUS or a synthetic resin such as a polyimide (PI) resin having heat resistance, and is formed of a cylindrical member having a relatively small length and a male thread 77a formed in an outer peripheral surface thereof. Recessed grooves 77b are formed in an outer end surface of the first adjusting ring 77 so as to be 180 degrees opposed to each other. When the first adjusting ring 77 is fastened and fitted into a first female thread portion 78 formed in the valve main body 6, a jig (not shown) for adjusting a fastening amount is locked to the recessed grooves 77b so as to turn the first adjusting ring 77.

As illustrated in FIG. 15, the first female thread portion 78 for fitting the first adjusting ring 77 is formed in the valve main body 6. A cylindrical portion 79 is formed at an opening end of the valve main body 6. The cylindrical portion 79 has a short length and has an outer diameter substantially equal to an outer diameter of the first adjusting ring 77. Further, a cylindrical portion 75d for processing is formed between the first female thread portion 78 and the cylindrical portion 75c of the valve main body 6. The cylindrical portion 75d for processing has a short length and an inner diameter larger than that of the first female portion 78 so as to allow processing for forming the first female portion 78 having a required length.

The first adjusting ring 77 is configured to adjust an amount (distance) of pushing and moving the first valve seat 70 inward by the first adjusting ring 77 through adjustment of a fastening amount of the first adjusting ring 77 with respect to the first female thread portion 78 of the valve main body 6. When the fastening amount of the first adjusting ring 77 is increased, as illustrated in FIG. 17, the first valve seat 70 is pushed by the first adjusting ring 77 via the first wave washer 16 and the first pressure-receiving plate 76 so that the concave portion 74 protrudes from an inner peripheral surface of the valve seat 8 and is displaced in a direction of approaching the valve shaft 34. Thus, the gap G1 between the concave portion 74 and the valve shaft 34 is reduced. Further, when the fastening amount of the first adjusting ring 77 is set to a small amount in advance, the distance of pushing and moving the first valve seat 70 by the first adjusting ring 77 is reduced. As a result, the first valve seat 70 is arranged apart from the valve shaft 34, and the gap G1 between the concave portion 74 of the first valve seat 70 and the valve shaft 34 is relatively increased. The male thread 77a of the first adjusting ring 77 and the first female thread portion 78 of the valve main body 6 are each set to have a small pitch. With this configuration, a protruding amount of the first valve seat 70 can be finely adjusted.

Further, as illustrated in FIG. 13, a first flange member 10 as one example of a connecting member, which is configured to connect a pipe, or the like (not shown), for allowing outflow of the fluid, is mounted to one side surface of the valve main body 6 with four hexagon socket head cap screws 11. In FIG. 12(b), a reference symbol 11a denotes a screw hole in which the hexagon socket head cap screw 11 is fastened. Similarly to the valve main body 6, the first flange member 10 is made of metal, for example, SUS. The first flange member 10 includes a flange portion 12, an insertion portion 13, and a pipe connecting portion 14. The flange portion 12 has a side surface having substantially the same rectangular shape as the side surface of the valve main body 6. The insertion portion 13 has a cylindrical shape having a short length and protrudes from an inner surface of the flange portion 12. The pipe connecting portion 14 has a substantially cylindrical shape having a large thickness and protrudes from an outer surface of the flange portion 12. A pipe (not shown) is connected to the pipe connecting portion 14. As illustrated in FIG. 13, a space between the flange portion 12 of the first flange member 10 and the valve main body 6 is sealed by an O-seal 13a. A recessed groove 13b configured to receive the O-seal 13a is formed in an inner peripheral surface of the flange portion 12 of the first flange member 10. An inner periphery of the pipe connecting portion 14 is set to, for example, Rc ½ being a standard for a tapered female thread having a bore diameter of about 21 mm, or a female thread having a diameter of about 0.58 inches. The shape of the pipe connecting portion 14 is not limited to the tapered female thread or the female thread. The pipe connecting portion 14 may have, for example, a tube fitting shape that allows a tube to be fitted thereto. The pipe connecting portion 14 may have any shape as long as the pipe connecting portion 14 enables outflow of a fluid through the first outflow port 7.

Here, the O-seal 13a is a sealing member having an O-ring shape, which is obtained by fully covering an outer side of a spring member with an elastically deformable synthetic resin made of a Teflon (trademark) tetrafluoroethylene-hexafluoropropylene copolymer (FEP) or the like. The spring member is made of stainless steel or the like and formed into a helical shape with a circular cross section or an elliptical cross section. The O-seal 13a can maintain hermetical sealability even at a low temperature of about −85° C.

As illustrated in FIG. 13, a second outflow port 17 and a second valve port 18 are formed in another side surface (right side surface in FIG. 13) of the valve main body 6. The second outflow port 17 allows outflow of a fluid. The second valve port 18 has a rectangular cross section as one example of communication port, and communicates with the valve seat 8 having the columnar space.

In the first embodiment, instead of directly forming the second outflow port 17 and the second valve port 18 in the valve main body 6, the second outflow port 17 and the second valve port 18 are formed in a second valve seat 80 that forms the second valve port 18 as one example of the valve port forming member and a second flow passage forming member 25 that forms the second outflow port 17 are fitted to the valve main body 6, thereby providing the second outflow port 17 and the second valve port 18.

The second valve seat 80 has a configuration similar to the configuration of the first valve seat 70 as illustrated in FIG. 16 with the reference symbol of the second valve seat 80 put in parentheses. That is, the second valve seat 80 integrally includes a cylindrical portion 81 and a tapered portion 82. The cylindrical portion 81 has a cylindrical shape and is provided outside the valve main body 6. The tapered portion 82 has an outer diameter decreasing toward the inner side of the valve main body 6. The second valve port 18 is formed in the tapered portion 82 of the second valve seat 80, and has a rectangular prism shape having a rectangular cross section (square cross section in the first embodiment). Further, one end portion of the second flow passage forming member 25 forming the second outflow port 17 is arranged so as to be inserted in a hermetically sealed state into the cylindrical portion 81 of the second valve seat 80.

As illustrated in FIG. 14, a recess 85 is formed in the valve main body 6 by, for example, machining. The recess 85 has a shape corresponding to an outer shape of the second valve seat 80 and similar to the shape of the valve seat 80. The recess 85 includes a cylindrical portion 85a corresponding to the cylindrical portion 81 of the second valve seat 80 and a tapered portion 85b corresponding to the tapered portion 82. A length of the cylindrical portion 85a of the valve main body 6 is set larger than a length of the cylindrical portion 81 of the second valve seat 80. As described later, the cylindrical portion 85a of the valve main body 6 forms a second pressure applying portion 96. The second valve seat 80 is fitted to the recess 85 of the valve main body 6 so as to be movable in a direction of moving close to and away from a valve shaft 34 serving as a valve body.

Under a state in which the second valve seat 80 is fitted to the recess 85 of the valve main body 6, a slight gap is defined between the second valve seat 80 and the recess 85 of the valve main body 6. A fluid having flowed into the valve seat 8 can flow into a region around an outer periphery of the second valve seat 80 through the slight gap. Further, the fluid having flowed into the region around the outer periphery of the second valve seat 80 is led into the second pressure applying portion 96 being a space defined on an outer side of the cylindrical portion 81 of the second valve seat 80. The second pressure applying portion 96 is configured to apply a pressure of the fluid to a surface 80a of the second valve seat 80 opposite to the valve shaft 34. The fluid flowing into the valve seat 8 is a fluid flowing out through the first valve port 9 as well as a fluid flowing out through the second valve port 18. The second pressure applying portion 98 is partitioned under a state in which the second flow passage forming member 25 seals the second pressure applying portion 98 with respect to the second outflow port 17.

The pressure of the fluid, which is to be applied to the valve shaft 34 arranged inside the valve seat 8, depends on a flow rate of the fluid determined by an opening/closing degree of the valve shaft 34. The fluid flowing into the valve seat 8 also flows (leaks) through the first valve port 9 and the second valve port 18 into a slight gap defined between the valve seat 8 and an outer peripheral surface of the valve shaft 34. Therefore, into the second pressure applying portion 96 adapted for the second valve seat 80, not only the fluid flowing out through the second valve port 18 flows (leaks), but also the fluid flowing into the slight gap defined between the valve seat 8 and the outer peripheral surface of the valve shaft 34 and flowing out through the first valve port 9 flows (leaks). The second valve seat 80 is made of the same material as that of the first valve seat 70.

As illustrated in FIG. 16(b), a concave portion 84 is formed at a distal end of the tapered portion 82 of the second valve seat 80. The concave portion 84 is one example of a gap reducing portion having an arc shape in plan view, which forms part of a curved surface of a columnar shape corresponding to the valve seat 8 having a columnar shape in the valve main body 6. A curvature radius R of the concave portion 84 is set to a value substantially equal to a curvature radius of the valve seat 8 or a curvature radius of a valve shaft 34. In order to prevent biting of the valve shaft 34 to be rotated inside the valve seat 8, as described later, the valve seat 8 of the valve main body 6 defines a slight gap with respect to an outer peripheral surface of the valve shaft 34. The concave portion 84 of the second valve seat 80 is fitted so as to protrude toward the valve shaft 34 side more than the valve seat 8 of the valve main body 6 or so as to be brought into contact with the outer peripheral surface of the valve shaft 34 under a state in which the second valve seat 80 is fitted to the valve main body 6. As a result, a gap G between the valve shaft 34 and an inner surface of the valve seat 8 of the valve main body 6 being a member opposed to the valve shaft 34 is partially set to a value reduced by the protruding amount of the concave portion 84 of the second valve seat 80 as compared to that of a gap between the valve shaft 34 and another portion of the valve seat 8. Thus, a gap G3 between the concave portion 84 of the second valve seat 80 and the valve shaft 34 is set to a desired value (G3<G2) smaller than (or a gap narrower than) the gap G2 between the valve shaft 34 and the inner surface of the valve seat 8. Further, the gap G3 between the concave portion 84 of the second valve seat 80 and the valve shaft 34 may correspond to a state in which the concave portion 84 of the second valve seat 80 is brought into contact with the valve shaft 34, that is, a state in which no gap is defined (the gap G3=0).

However, in a case in which the concave portion 84 of the second valve seat 80 is brought into contact with the valve shaft 34, there is a fear in that driving torque of the valve shaft 34 is increased due to contact resistance of the concave portion 84 when the valve shaft 34 is driven to rotate. Accordingly, a contact degree of the concave portion 84 of the second valve seat 80 with the valve shaft 34 is adjusted in consideration of the rotational torque of the valve shaft 34. That is, the contact degree is adjusted to such an extent as to involve no increase in the driving torque of the valve shaft 34 or involve slight increase even when the driving torque is increased, and cause no trouble for rotation of the valve shaft 34.

As illustrated in FIG. 15, the second flow passage forming member 25 is made of metal such as SUS or a synthetic resin such as a polyimide (PI) resin, and has a cylindrical shape. The second flow passage forming member 25 has the second outflow port 17 formed therein to communicate with the second valve port 18 irrespective of shift of a position of the second valve seat 80. About half of the second flow passage forming member 25, which is positioned on the second valve seat 80 side, is formed as a small-thickness cylindrical portion 25a having a cylindrical shape with a relatively small thickness. Further, about half of the second flow passage forming member 25, which is positioned on a side opposite to the second valve seat 80, is formed as a large-thickness cylindrical portion 25b having a cylindrical shape with a larger thickness than a thickness of the cylindrical portion with a small thickness. An inner surface of the second flow passage forming member 25 has a cylindrical shape and penetrates the second flow passage forming member 25. A flange portion 25c having an annular shape is formed between the small-thickness cylindrical portion 25a and the large-thickness cylindrical portion 25b on an outer periphery of the second flow passage forming member 25. The flange portion 25c has a relatively large thickness and extends radially outward. An outer peripheral end of the flange portion 25c is arranged in contact with an inner peripheral surface of the recess 85 so as to be movable therealong.

As illustrated in FIG. 13, a gap between the cylindrical portion 81 of the second valve seat 80 and the small-thickness cylindrical portion 25a of the second flow passage forming member 25 is hermetically sealed (sealed) by a first spring energized seal 140, which is one example of first sealing means. The first spring energized seal 140 is made of a synthetic resin, has a substantially U-shaped cross section, and is urged in an opening direction by a spring member made of metal. As illustrated in FIGS. 16, a stepped portion 83 for receiving the first spring energized seal 140 therein is formed in an end portion of an inner peripheral surface of the cylindrical portion 81 of the second valve seat 80, which is positioned on an outer side of the valve main body 6.

As illustrated in FIGS. 18, the first spring energized seal 140 is constructed in the same manner as the first spring energized seal 120. The first spring energized seal 140 includes a spring member and a sealing member. When the pressure of the fluid is not applied to the first spring energized seal 140 or the pressure of the fluid is relatively low, the first spring energized seal 140 hermetically seals the gap between the second valve seat 80 and the second flow passage forming member 25 with an elastic restoration force of the spring member. Meanwhile, when the pressure of the fluid is relatively high, the first spring energized seal 140 hermetically seals the gap between the second valve seat 80 and the second flow passage forming member 25 with the elastic restoration force of the spring member and the pressure of the fluid. Thus, even when the fluid flows into the second pressure applying portion 96 through the gap between the inner peripheral surface of the valve main body 6 and the outer peripheral surface of the second valve seat 80, the gap between the second valve seat 80 and the second flow passage forming member 25 is sealed by the first spring energized seal 140 and thus the fluid does not flow into the second flow passage forming member 25.

As illustrated in FIG. 13 and FIG. 14, the end surface 80a of the cylindrical portion 81 of the second valve seat 80 is a region (pressure-receiving surface) that receives the pressure of the fluid applied by the second pressure applying portion 96.

In the first embodiment, the stepped portion 83 for allowing the first spring energized seal 140 to be mounted therein is formed in the end surface 80a of the cylindrical portion 81 of the second valve seat 80. Thus, the end surface 80a of the cylindrical portion 81 of the second valve seat 80 has a structure that is less liable to receive all the pressure of the pressure of the fluid applied by the second pressure applying portion 96 because of the presence of the stepped portion 83.

Thus, in the first embodiment, as illustrated in FIG. 13 and FIG. 14, a second pressure-receiving plate 86 having an annular shape is provided so that the pressure of the fluid is effectively applied to the end surface 80a of the cylindrical portion 81 of the second valve seat 80 by the second pressure applying portion 96. The second pressure-receiving plate 86 covers the end surface 80a of the cylindrical portion 81 of the second valve seat 80, which includes the stepped portion 83 of the second valve seat 80, to achieve closure. Specifically, the second pressure-receiving plate 86 is arranged in contact with the end surface 80a of the cylindrical portion 81 of the second valve seat 80 so as to close the stepped portion 83. The second pressure-receiving plate 86 is made of the same material as that of the second valve seat 80. Further, a slight gap is set between an outer peripheral end surface of the second pressure-receiving plate 86 in its radial direction and the recess 85 of the valve main body 6 so as to allow the fluid to leak into the second pressure applying portion 96.

Meanwhile, a gap between an end portion of the large-thickness cylindrical portion 25b, which is another end portion of the second flow passage forming member 25, and the inner peripheral surface of the valve main body 6 is hermetically sealed (sealed) by a second spring energized seal 150. The second spring energized seal 150 is one example of second sealing means that is made of a synthetic resin, has a substantially U-shaped cross section, and is urged in an opening direction by a spring member made of metal. As illustrated in FIG. 15, a cylindrical portion 85c that allows the second spring energized seal 150 to be mounted therein is formed on the inner peripheral surface of the valve main body 6. The cylindrical portion 85c having a short length is formed at an outer end portion of the cylindrical portion 85a of the recess 85 in the axial direction, and has an outer diameter slightly larger than that of the cylindrical portion 85a of the recess 85. The length of the cylindrical portion 85c is set longer than a length of the second spring energized seal 150.

A gap between the cylindrical portion 85c of the valve main body 6 and the large-thickness cylindrical portion 25b of the second flow passage forming member 25 is hermetically sealed (sealed) by the second spring energized seal 150. The second spring energized seal 150 is opened toward the second pressure applying portion 96. Specifically, the second spring energized seal 150 is arranged so that its opening receives the pressure of the fluid applied by the second pressure applying portion 96. Although the second spring energized seal 150 has the outer diameter larger than that of the first spring energized seal 140, the second spring energized seal 150 is basically constructed in the same manner as the first spring energized seal 140.

A second wave washer (corrugated washer) 26 is provided on an outer side of the cylindrical portion 81 of the second valve seat 80. The second wave washer 26 is one example of an elastic member configured to push and move the second valve seat 80 in a direction of coming into contact with the valve shaft 34 while allowing displacement of the second valve seat 80 in a direction of moving close to and away from the valve shaft 34. As illustrated in FIGS. 21, the second wave washer 26 is made of, for example, stainless steel, iron, or phosphor bronze, and has an annular shape having a desired width when a front side thereof is projected. Further, a side surface of the second wave washer 26 is formed into a wavy (corrugated) shape, and the second wave washer 26 is elastically deformable in a thickness direction thereof. An elastic modulus of the second wave washer 26 is determined by, for example, the thickness, a material, or the number of waves of the second wave washer 26. The second wave washer 26 equivalent to the first wave washer 16 is used.

Moreover, a second adjusting ring 87 is arranged on an outer side of the second wave washer 26. The second adjusting ring 87 is one example of an adjusting member configured to adjust the gap G3 between the valve shaft 34 and the concave portion 84 of the second valve seat 80 via the second wave washer 26. As illustrated in FIG. 22, the second adjusting ring 87 is made of a synthetic resin having heat resistance or metal, and is formed of a cylindrical member having a relatively small length and a male thread 87a formed in an outer peripheral surface thereof. Recessed grooves 87b are formed in an outer end surface of the second adjusting ring 87 so as to be 180 degrees opposed to each other. When the second adjusting ring 87 is fastened and fitted into a second female thread portion 88 formed in the valve main body 6, a jig (not shown) for adjusting a fastening amount is locked to the recessed grooves 87b so as to turn the second adjusting ring 87.

As illustrated in FIG. 15, a second female thread portion 88 for fitting the second adjusting ring 87 is formed in the valve main body 6. A cylindrical portion 89 is formed at an opening end of the valve main body 6. The cylindrical portion 89 has a short length and has an outer diameter substantially equal to an outer diameter of the second adjusting ring 87. Further, a cylindrical portion 85d for processing is formed between the second female thread portion 88 and the cylindrical portion 85c of the valve main body 6. The cylindrical portion 85d for processing has a short length and an inner diameter larger than that of the second female portion 88 so as to allow processing for forming the second female portion 88 having a required length.

The second adjusting ring 87 is configured to adjust an amount (distance) of pushing and moving the second valve seat 80 inward by the second adjusting ring 877 via the second wave washer 26 through adjustment of a fastening amount of the second adjusting ring 87 with respect to the second female thread portion 88 of the valve main body 6. When the fastening amount of the second adjusting ring 87 is increased, as illustrated in FIG. 17, the second valve seat 80 is pushed by the second adjusting ring 87 via the second wave washer 26 so that the concave portion 84 protrudes from an inner peripheral surface of the valve seat 8 and is displaced in a direction of approaching the valve shaft 34. Thus, the gap G3 between the concave portion 84 and the valve shaft 34 is reduced. Further, when the fastening amount of the second adjusting ring 87 is set to a small amount in advance, the distance of pushing and moving the second valve seat 80 by the second adjusting ring 87 is reduced. As a result, the second valve seat 80 is arranged apart from the valve shaft 34, and the gap G3 between the concave portion 84 of the second valve seat 80 and the valve shaft 34 is relatively increased. The male thread 87a of the second adjusting ring 87 and the second female thread portion 88 of the valve main body 6 are each set to have a small pitch. With this configuration, a protruding amount of the second valve seat 80 can be finely adjusted.

As illustrated in FIG. 13, a second flange member 19 as one example of a connecting member for connecting a pipe (not shown) which allows outflow of the fluid is mounted to the another side surface of the valve main body 6 with four hexagon socket head cap screws 20. Similarly to the first flange member 10, the second flange member 19 is made of metal, for example, SUS. The second flange member 19 has a flange portion 21, an insertion portion 22, and a pipe connecting portion 23. The flange portion 21 has a side surface having the same rectangular shape as the side surface of the valve main body 6. The insertion portion 22 has a cylindrical shape and protrudes from an inner surface of the flange portion 21. The pipe connecting portion 23 has a substantially cylindrical shape having a large thickness and protrudes from an outer surface of the flange portion 21. A pipe (not shown) is connected to the pipe connecting portion 23. As illustrated in FIG. 2, a space between the flange portion 21 of the second flange member 19 and the valve main body 6 is sealed by an O-seal 21a. An annular recessed groove 21b configured to receive the O-seal 21a is formed in an inner peripheral surface of the flange portion 21 of the second flange member 19. An inner periphery of the pipe connecting portion 23 is set to, for example, Rc ½ being a standard for a tapered female thread having a bore diameter of about 21 mm, or a female thread having a diameter of about 0.58 inches. Similarly to the pipe connecting portion 14, the shape of the pipe connecting portion 23 is not limited to the tapered female thread or the female thread. The pipe connecting portion 23 may have, for example, a tube fitting shape that allows a tube to be fitted thereto. The pipe connecting portion 23 may have any shape as long as the pipe connecting portion 23 enables outflow of a fluid through the second outflow port 17.

Here, examples of a fluid (brine) include fluorine-based inert liquids such as Opteon (trademark: manufactured by Chemours-Mitsui Fluoroproducts Co., Ltd.) and Novec (trademark: manufactured by 3M company), which are adaptable and used, for example, at a pressure of from 0 MPa to 1 MPa and in a temperature range of from about −85° C. to about +120° C.

Further, as illustrated in FIG. 13, in a lower end surface of the valve main body 6, an inflow port 26b having a circular cross section as the third valve port is opened. The inflow port 26b allows inflow of a fluid. A third flange member 27 as one example of a connecting member for connecting a pipe (not shown) which allows inflow of the fluid is mounted to the lower end surface of the valve main body 6 with four hexagon socket head cap screws 28. A cylindrical portion 26a is opened at a lower end portion of the inflow port 26b. The cylindrical portion 26a has an inner diameter larger than that of the inflow port 26b so as to allow the third flange member 27 to be mounted thereinto. The third flange member 27 includes a flange portion 29, an insertion portion 30, and a pipe connecting portion 31. The flange portion 29 has a bottom surface having the rectangular shape. The insertion portion 30 has a cylindrical shape having a short length and protrudes from an inner surface of the flange portion 29 (see FIG. 13). The pipe connecting portion 31 has a substantially cylindrical shape having a large thickness and protrudes from an outer surface of the flange portion 29. A pipe (not shown) is connected to the pipe connecting portion 31. As illustrated in FIG. 2, a space between the flange portion 29 of the third flange member 27 and the valve main body 6 is sealed by an O-seal 29a. A recessed groove 29b configured to receive the O-seal 29a is formed in an inner peripheral surface of the flange portion 29 of the third flange member 27. An inner periphery of the pipe connecting portion 31 is set to, for example, Rc ½ being a standard for a tapered female thread having a bore diameter of about 21 mm and a female thread having a diameter of about 0.58 inches. The shape of the pipe connecting portion 31 is not limited to the tapered female thread or the female thread. The pipe connecting portion 31 may have, for example, a tube fitting shape that allows a tube to be fitted thereto. The pipe connecting portion 31 may have any shape as long as the pipe connecting portion 31 enables inflow of a fluid through the inflow port 26b.

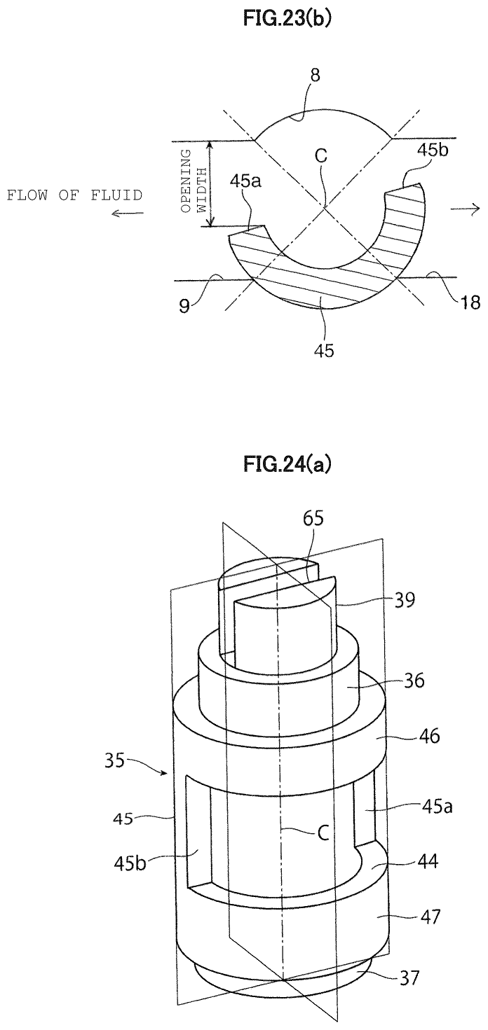

As illustrated in FIG. 14, the valve seat 8 is formed in a center of the valve main body 6. The valve seat 8 forms the first valve port 9 having a rectangular cross section and the second valve port 18 having a rectangular cross section when the first valve seat 70 and the second valve seat 80 are fitted to the valve main body 6. The valve seat 8 has a space having a columnar shape corresponding to an outer shape of a valve body to be described later. Further, part of the valve seat 8 is formed by the first valve seat 70 and the second valve seat 80. The valve seat 8 having a columnar shape is provided in a state of penetrating an upper end surface of the valve main body 6. As illustrated in FIGS. 23, the first valve port 9 and the second valve port 18 provided to the valve main body 6 are arranged in an axial symmetrical manner with respect to a center axis (rotation axis) C of the valve seat 8 having a columnar shape. More specifically, the first valve port 9 and the second valve port 18 are arranged so as to be orthogonal to the valve seat 8 having a columnar shape. One end edge of the first valve port 9 is opened in a position opposed to another end edge of the second valve port 18 through the center axis C, that is, in a position different by 180°. Further, another end edge of the first valve port 9 is opened in a position opposed to one end edge of the second valve port 18 through the center axis C, that is, in a position different by 180°. In FIGS. 13, for convenience, illustration of a gap between the valve seat 8 and the valve shaft 34 is omitted.

Further, as illustrated in FIG. 13, the first valve port 9 and the second valve port 18 are openings each having a rectangular cross section such as a square cross section and are formed through fitting through fitting of the first valve seat 70 and the second valve seat 80 to the valve main body 6 as described above. A length of one side of the first valve port 9 and the second valve port 18 is set to be smaller than a diameter of the first outflow port 7 and the second outflow port 17. The first valve port 9 and the second valve port 18 have rectangular tube shape having a rectangular cross section inscribed in the first outflow port 7 and the second outflow port 17.

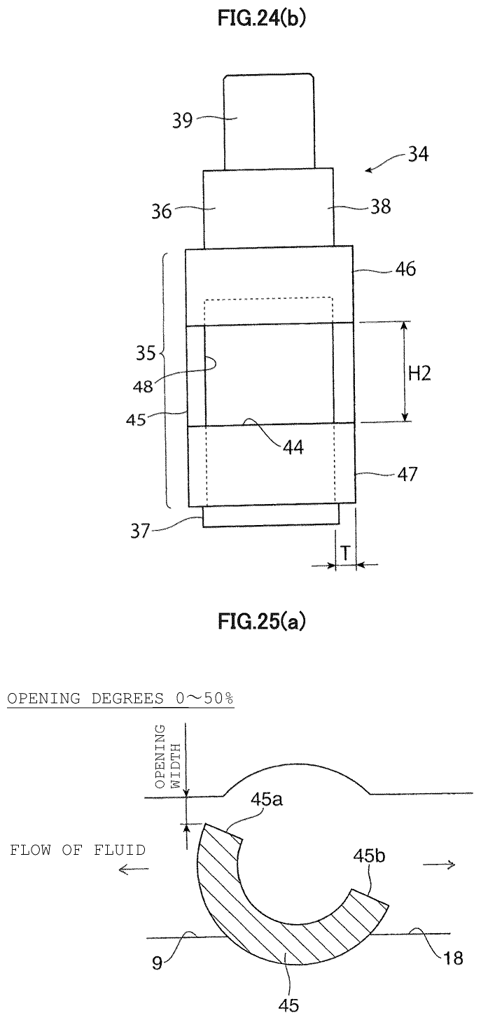

As illustrated in FIGS. 24, a valve shaft 34 as one example of the valve body has an outer shape obtained by forming metal, for example, SUS, into a substantially columnar shape. The valve shaft 34 mainly includes a valve body portion 35, upper and lower shaft support parts 36 and 37, a sealing portion 38, and a coupling portion 39, which are integrally provided. The valve body portion 35 functions as a valve body. The upper and lower shaft support parts 36 and 37 are provided above and below the valve body portion 35, respectively, and support the valve shaft 34 in a freely rotatable manner. The sealing portion 38 includes the same components as those of the upper shaft support portion 36. The coupling portion 39 is provided to an upper portion of the sealing portion 38.

The upper and lower shaft support parts 36 and 37 each have a cylindrical shape having an outer diameter smaller than that of the valve body portion 35 and having an equal or a different diameter. As illustrated in FIG. 15, the lower shaft support portion 37 is supported in a rotatable manner through intermediation of a bearing 41 serving as a bearing member by a lower end of the valve seat 8 provided to the valve main body 6. An annular support portion 42 supporting the bearing 41 is provided at a lower portion of the valve seat 8. The bearing 41, the support portion 42, and the inflow port 26b are set to have a substantially equal inner diameter, and are configured to allow inflow of the fluid for temperature control to an inside of the valve body portion 35 with little resistance.

Further, as illustrated in FIG. 13 and FIG. 24(b), the valve body portion 35 has a cylindrical shape having an opening 44 formed therein. The opening 44 has a substantially half-cylindrical shape with an opening height Hg2, which is smaller than an opening height Hg1 of the first and second valve ports 9 and 18. A valve operating portion 45 having the opening 44 of the valve body portion 35 has a half-cylindrical shape (substantially half-cylindrical shape of a cylindrical portion excluding the opening 44) with a predetermined central angle α (for example, 180°). The valve operating portion 45 is arranged in a freely rotatable manner in the valve seat 8 and held in non-contact with an inner peripheral surface of the valve seat 8 through a slight gap to prevent metal-to-metal biting. Accordingly, with the valve body portion 35 positioned above and below the opening 44 included, the valve operating portion 45 simultaneously switches the first valve port 9 from a closed state to an opened state and the second valve port 18 from an opened state to a closed state in a reverse direction. As illustrated in FIG. 13, upper and lower valve shaft parts 46 and 47 arranged above and below the valve operating portion 45 each have a cylindrical shape having an outer diameter equal to that of the valve operating portion 45, and are held in non-contact with the inner peripheral surface of the valve seat 8 in a freely rotatable manner through a slight gap. In an inside the valve operating portion 45, and the upper and lower valve shaft parts 46 and 47, a space 48 is provided in a state of penetrating the valve shaft 34 toward a lower edge thereof. The space 48 has a columnar shape.

Further, a cross section of each of both end surfaces 45a and 45b of the valve operating portion 45 in a circumferential direction (rotation direction), which is taken along a direction intersecting (orthogonal to) the center axis C, has a flat-surface shape. More specifically, as illustrated in FIGS. 24, the cross section of each of the both end surfaces 45a and 45b of the valve operating portion 45 in the circumferential direction, which is taken along a direction intersecting the rotation axis C, has a flat-surface shape toward the opening 44. A thickness of each of the both end surfaces 45a and 45b is set to, for example, an equal value of a thickness T of the valve operating portion 45.

The cross section of each of the both end surfaces 45a and 45b of the valve operating portion 45 in the circumferential direction, which is taken along a direction intersecting the rotation axis C, is not limited to a flat-surface shape. Each of the both end surfaces 45a and 45b in the circumferential direction (rotation direction) may have a curved-surface shape.

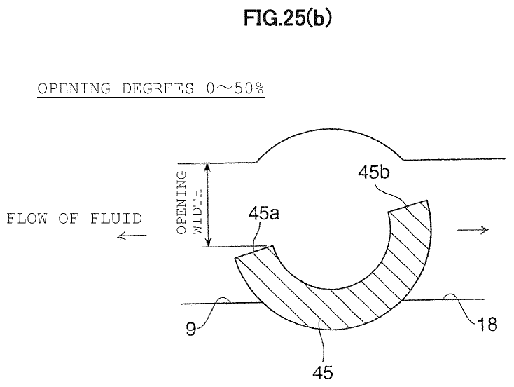

As illustrated in FIGS. 25, when the valve shaft 34 is driven to rotate to open and close the first and second valve ports 9 and 18, in flows of the fluid, the both end surfaces 45a and 45b of the valve operating portion 45 in the circumferential direction are moved (rotated) so as to protrude from or retreat to the ends of the first and second valve ports 9 and 18 in the circumferential direction. Accordingly, the first and second valve ports 9 and 18 are switched from the opened state to the closed state, or from the closed state to the opened state. At this moment, it is desired that each of the both end surfaces 45a and 45b of the valve operating portion 45 in the circumferential direction have a cross section having a flat-surface shape so as to linearly change opening areas of the first and second valve ports 9 and 18 with respect to a rotation angle of the valve shaft 34.

As illustrated in FIG. 13, the sealing portion 4 hermetically seals (seals) the valve shaft 34 in a liquid-tight state so that the valve shaft 34 is rotatable with respect to the valve main body 6. The sealing portion 4 includes the valve main body 6, the valve shaft 34, spring energized seals 160 and 170, and a bearing member 180. The spring energized seals 160 and 170 are each one example of sealing means that is made of a synthetic resin, has a substantially U-shaped cross section, and is urged in an opening direction by a spring member made of metal. The spring energized seals 160 and 170 are arranged between the valve main body 6 and the valve shaft 34 to seal a gap between the valve main body 6 and the valve shaft 34 in a liquid-tight manner. The bearing member 180 supports the valve shaft 34 so that the valve shaft 34 is rotatable with respect to a valve main body.

As illustrated in FIG. 13, a recess portion 51 for support is formed at an upper end portion of the valve main body 6. The recess portion 51 for support has a columnar shape and allows the valve shaft 34 to be rotatably supported. A cylindrical portion 51b having a large inner diameter is formed at an upper end of the recess portion 51 for support so as to be continuous with a tapered portion 51a. As described above, the upper valve shaft portion 46 of the valve shaft 34 is rotatably supported in a liquid-tight manner in a lower end portion of the recess portion 51 for support through intermediation of the bearing member 180, which is one example of a bearing member, and the spring energized seals 160 and 170.

As illustrated in FIGS. 12, the coupling portion 5 is arranged between the valve main body 6, in which the sealing portion 4 is provided, and the actuator 3. The coupling portion 5 is configured to connect the valve shaft 34 and a rotation shaft shown), which allows the valve shaft 34 to be integrally rotated, to each other.

As illustrated in FIG. 13, the coupling portion 5 includes a spacer member 59, an adaptor plate 60, and a coupling member 62. The spacer member 59 is arranged between the sealing portion 4 and the actuator 3. The adaptor plate 60 is fixed to an upper portion of the spacer member 59. The coupling member 62 is accommodated in a space 61 having a columnar shape formed in a state of penetrating an inside of the spacer member 59 and the adaptor plate 60, and connects the valve shaft 34 and the rotation shaft (not shown) to each other. The spacer member 59 is obtained by forming a synthetic resin such as a polyimide (PI) resin, into a rectangular tube shape, which has substantially the same shape in plan view as that of the part of the valve main body 6 and a relatively large height. The spacer member 59 is fixed to both the valve main body 6 and the adaptor plate 60 through means such as screw 59b fastening of the flange portion 59a provided on the lower end thereof. Further, as illustrated in FIG. 12(c), the adaptor plate 60 is obtained by forming metal, for example, SUS, into a plate-like shape having a planar polygonal shape. The adaptor plate 60 is mounted to the base 64 of the actuator 3 in a fixed state with hexagon socket head cap screws 63.

As illustrated in FIG. 24(a), a recessed groove 65 is formed so as to penetrate an upper end of the valve shaft 34 in a horizontal direction. The valve shaft 34 is coupled and fixed to the coupling member 62 by fitting a projecting portion 66 of the coupling member 62 into the recessed groove 65. Meanwhile, a recessed groove 67 is formed in an upper end of the coupling member 62 so as to penetrate the coupling member 62 in a horizontal direction. The rotation shaft (not shown) is coupled and fixed to the coupling member 62 by fitting a projecting portion (not shown) into the recessed groove 67 of the coupling member 62. The spacer member 59 includes an O-seal 190 at its upper end portion. When liquid leaks from the sealing portion 4, the O-seal 190 prevents the liquid from reaching the actuator 3.

As illustrated in FIGS. 12, the actuator 3 includes the base 64 having a planar surface having a rectangular shape. A casing 90 is mounted to an upper portion of the base 64 with screws 91. The casing 90 is constructed as a box body having a rectangular parallelepiped shape, which contains drive means including a stepping motor, an encoder, and the like. The drive means in the actuator 3 only needs to be capable of rotating the rotation shaft (not shown) in a desired direction with predetermined accuracy based on control signals, and configuration thereof is not limited. The drive means includes a stepping motor, a driving force transmission mechanism, and an angle sensor. The driving force transmission mechanism is configured to transmit a rotational driving force of the stepping motor to the rotation shaft through intermediation of driving force transmission means, for example, a gear. The angle sensor is, for example, an encoder or the like configured to detect a rotation angle of the rotation shaft.

In FIGS. 12, a reference symbol 92 denotes a stepping motor-side cable, and a reference symbol 93 denotes an angle sensor-side cable. The stepping motor-side cable 92 and the angle sensor-side cable 93 are connected to a control device (not shown) configured to control the three-way motor valve 1.

### <Environmental Conditions>

As described above, the three-way motor valve 1 according to the first embodiment is constructed so as to be usable for a fluid having a temperature within a range of, for example, from about −85° C. to about +120° C., in particular, a significantly low temperature of about −85° C. Thus, it is desired that surrounding environmental conditions under which the three-way motor valve 1 is used be determined in consideration of the temperature range of from about −85° C. to about +120° C. Specifically, when a fluid at about −85° C. is allowed to flow through the three-way motor valve 1, the valve main body 6 itself has a temperature equal to about −85° C., which is the temperature of the fluid. As a result, when a condition under which the three-way motor valve 1 is used is a humid environment containing water in air, the water in air adheres to the three-way motor valve 1 and is frozen. Thus, it is considered that the freezing may cause malfunction of the three-way motor valve 1.

Accordingly, in the first embodiment, it is desired that an ambient humidity (relative humidity) be 0.10% or lower, preferably about 0.01% under an environment replaced with a nitrogen (N²⁻) gas as an environmental condition under which the three-way motor valve 1 is used.

### <Motion of Three-Way Motor Valve>

When a fluid having a low temperature of about −85° C. is allowed to flow through the three-way motor valve 1 according to the first embodiment, a flow rate of the fluid is controlled in the following manner.

As illustrated in FIG. 15, at the time of assembly or adjustment for use, in the three-way motor valve 1, the first flange member 10 and the second flange member 19 are once removed from the valve main body 6 so that the adjusting rings 77 and 87 are exposed to the outside. Under this state, when the fastening amounts of the adjusting rings 77 and 87 with respect to the valve main body 6 are adjusted through use of the jig (not shown), as illustrated in FIG. 17, the protruding amounts of the first valve seat 70 and the second valve seat 80 from the valve seat 8 of the valve main body 6 are changed. When the fastening amounts of the adjusting rings 77 and 87 with respect to the valve main body 6 are increased, the concave portions 74 of the first valve seat 70 or the concave portion 84 of the second valve seat 80 protrudes from the inner peripheral surface of the valve seat 8 of the valve main body 6 so that the gap G1 between the outer peripheral surface of the valve shaft 34 and the concave portion 74 of the first valve seat 70 or the concave portion 84 of the second valve seat 80 is reduced. Accordingly, the outer peripheral surface of the valve shaft 34 is brought into contact with the concave portion 74 of the first valve seat 70 or the concave portion 84 of the second valve seat 80. Meanwhile, when the fastening amounts of the adjusting rings 77 and 87 with respect to the valve main body 6 are reduced, a protruding length of the concave portion 74 of the first valve seat 70 or the concave portion 84 of the second valve seat 80 from the inner peripheral surface of the valve seat 8 of the valve main body 6 is reduced so that the gap G1 between the outer peripheral surface of the valve shaft 34 and the concave portion 74 of the first valve seat 70 or the concave portion 84 of the second valve seat 80 is increased.

In the first embodiment, for example, the gap G1 between the outer peripheral surface of the valve shaft 34 and the concave portion 74 of the first valve seat 70 or the concave portion 84 of the second valve seat 80 is set to be smaller than 10 μm. However, the gap G1 between the outer peripheral surface of the valve shaft 34 and the concave portion 74 of the first valve seat 70 or the concave portion 84 of the second valve seat 80 is not limited to the above-mentioned value. The gap G1 may be set to a value smaller than the above-mentioned value, for example, may satisfy the gap G1=0 μm (contact state). Alternatively, the gap G1 may be set to 10 μm or more.

As illustrated in FIG. 13, in the three-way motor valve 1, the fluid flows in from the third flange member 27 via pipes (not shown), and the fluid flows out from the first flange member 10 and the second flange member 19 via pipes (not shown). Further, as illustrated in FIG. 14(a), for example, in an initial state before start of operation, the three-way motor valve 1 is brought into a state in which the valve operating portion 45 of the valve shaft 34 simultaneously closes (completely closes) the first valve port 9 and opens (completely opens) the second valve port 18.

As illustrated in FIGS. 12, in the three-way motor valve 1, when the stepping motor (not shown) provided in the actuator 3 is driven to rotate by a predetermined amount, the rotation shaft (not shown) is driven to rotate in accordance with a rotation amount of the stepping motor. In the three-way motor valve 1, when the rotation shaft is driven to rotate, the valve shaft 34 coupled and fixed to the rotation shaft is rotated by an angle equivalent to the rotation amount (rotation angle) of the rotation shaft. The valve operating portion 45 is rotated in the valve seat 8 along with the rotation of the valve shaft 34. As illustrated in FIG. 23(a), the one end surface 45a of the valve operating portion 45 in the circumferential direction gradually opens the first valve port 9. As a result, the fluid flows into the valve seat 8 through the first inflow port 26b, and flows out from the first flange member 10 through the first outflow port 7.

At this time, as illustrated in FIG. 25(a), another end surface 45b of the valve operating portion 45 in the circumferential direction opens the second valve port 18. Thus, the fluid having flowed in through the inflow port 26b flows into the valve seat 8 and is distributed in accordance with a rotation amount of the valve shaft 34, and flows out from the second flange member 19 through the second outflow port 17.

As illustrated in FIG. 25(a), in the three-way motor valve 1, when the valve shaft 34 is rotationally driven, the one end surface 45a of the valve operating portion 45 in the circumferential direction gradually opens the first valve port 9. As a result, the fluid passes through the valve seat 8 and an inside of the valve shaft 34 and is supplied via the first valve port 9 and the second valve port 18 to an outside through the first outflow port 7 and the second outflow port 17.

Further, in the three-way motor valve 1, each of the both end surfaces 45a and 45b of the valve operating portion 45 in the circumferential direction has a cross section having a curved-surface shape or a flat-surface shape. Thus, the opening areas of the first and second valve ports 9 and 18 can be linearly changed with respect to the rotation angle of the valve shaft 34. Further, it is conceivable that the fluid regulated in flow rate by the both end surfaces 45a and 45b of the valve operating portion 45 flow in a form of a nearly laminar flow. Therefore, the distribution ratio (flow rate) between the fluid can be controlled with high accuracy in accordance with the opening areas of the first valve port 9 and the second valve port 18.

In the three-way motor valve 1 according to the first embodiment, as described above, under an initial state, the valve operating portion 45 of the valve shaft 34 simultaneously closes (completely closes) the first valve port 9 and opens (completely opens) the second valve port 18.

At this time, in the three-way motor valve 1, when the valve operating portion 45 of the valve shaft 34 closes (completely closes) the first valve port 9, ideally, the flow rate of the fluid should be zero.

However, as illustrated in FIG. 17, in the three-way motor valve 1, in order to prevent metal-to-metal biting of the valve shaft 34 into the inner peripheral surface of the valve seat 8, the valve shaft 34 is provided in a freely rotatable manner so as to be held in non-contact with the valve seat 8 with a slight gap between the outer peripheral surface of the valve shaft 34 and the inner peripheral surface of the valve seat 8. As a result, the slight gap G2 is defined between the outer peripheral surface of the valve shaft 34 and the inner peripheral surface of the valve seat 8. Accordingly, in the three-way motor valve 1, even when the valve operating portion 45 of the valve shaft 34 closes (completely closes) the first valve port 9, the flow rate of the fluid does not become zero, and a small amount of the fluid flows to the second valve port 18 side through the slight gap G2 defined between the outer peripheral surface of the valve shaft 34 and the inner peripheral surface of the valve seat 8.

Incidentally, in the three-way motor valve 1 according to the first embodiment, as illustrated in FIG. 17, the first valve seat 70 and the second valve seat 80 include the concave portion 74 and the concave portion 84, respectively. The concave portion 74 or the concave portion 84 protrudes from the inner peripheral surface of the valve seat 8 toward the valve shaft 34 side, thereby partially reducing the gap G1 between the outer peripheral surface of the valve shaft 34 and the inner peripheral surface of the valve seat 8.

Therefore, in the three-way motor valve 1, in order to prevent metal-to-metal biting of the valve shaft 34 into the inner peripheral surface of the valve seat 8, even when the valve shaft 34 is provided in a freely rotatable manner so as to be held in non-contact with the valve seat 8 with the slight gap between the outer peripheral surface of the valve shaft 34 and the inner peripheral surface of the valve seat 8, inflow of the fluid through the first valve port 9 into the slight gap G2 defined between the outer peripheral surface of the valve shaft 34 and the inner peripheral surface of the valve seat 8 is significantly restricted and suppressed by the gap G1 that is a region corresponding to a partially reduced gap between the outer peripheral surface of the valve shaft 34 and the inner peripheral surface of the valve seat 8.

Accordingly, the three-way motor valve 1 can significantly suppress leakage of the fluid when the three-way motor valve 1 completely closes the valve port as compared to a three-way motor valve that does not include the concave portions 74 and 84 formed to partially reduce the gap between the valve shaft 34 and the first valve seat 70, which is opposed to the valve shaft 34, and the gap between the valve shaft 34 and the second valve seat 80, which is opposed to the valve shaft 34.

Preferably, the three-way motor valve 1 according to the first embodiment can significantly reduce the gaps G1 and G2 through contact of the concave portion 74 of the first valve seat 70 and the concave portion 84 of the second valve seat 80 with the outer peripheral surface of the valve shaft 34, thereby significantly suppressing leakage of the fluid when the three-way motor valve 1 completely closes the valve port.

Further, similarly, the three-way motor valve 1 can significantly suppress leakage and outflow of the fluid through the second valve port 18 to another first valve port 9 side even when the valve operating portion 45 of the valve shaft 34 closes (completely closes) the second valve port 18.

Moreover, as illustrated in FIG. 14 and FIGS. 16, in the first embodiment, the first pressure applying portion 94 and the second pressure applying portion 96 are respectively provided to the surface 70a of the first valve seat 70 and the surface 80a of the second valve seat 80 that are opposite to the valve shaft 34. The first pressure applying portion 94 and the second pressure applying portion 96 are configured to apply the pressure of the fluid through the slight gap between the outer peripheral surface of the valve shaft 34 and the inner peripheral surface of the valve seat 8. Accordingly, as illustrated in FIG. 23(a), in the three-way motor valve 1, under a state in which an opening degree is 0%, that is, the first valve port 9 is nearly completely closed, and under a state in which the opening degree is 100%, that is, the first valve port 9 is nearly completely opened, when the first valve port 9 and the second valve port 18 are each brought closer to a completely closed state, an amount of outflow of the fluid through the first valve port 9 and the second valve port 18 is significantly reduced. Along with this, in the three-way motor valve 1, in the valve port brought closer to a completely closed state, the pressure of the fluid flowing out through the first valve port 9 or the second valve port 18 is reduced. Thus, for example, when the opening degree is 0%, that is, the first valve port 9 is completely closed, the fluid having a pressure of about 700 KPa flows in through the inflow port 26b, and then flows out through the second valve port 18 while maintaining the pressure of about 700 KPa. At this time, on the side of the first valve port 9 that is nearly completely closed, a pressure on an outflow side is reduced to, for example, about 100 KPa. As a result, there is a difference in pressure of about 600 KPa between the second valve port 18 and the first valve port 9.

Therefore, in the three-way motor valve 1 against which no countermeasures are taken, due to the difference in pressure between the second valve port 18 and the first valve port 9, the valve shaft 34 is moved (displaced) to the side of the first valve port 9 under a relatively low pressure so that the valve shaft 34 is held in unbalanced contact with the bearing 41. As a result, there is a fear in that driving torque is increased when the valve shaft 34 is driven to rotate in a direction of closing the valve shaft 34, thereby causing operation malfunction.

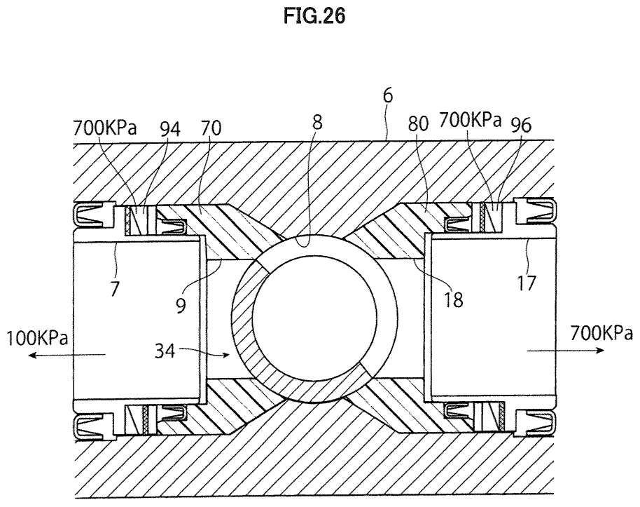

In contrast, in the three-way motor valve 1 according to the first embodiment, as illustrated in FIG. 26, the first pressure applying portion 94 and the second pressure applying portion 96 are respectively provided to the surface of the first valve seat 70 and the surface of the second valve seat 80 that are opposite to the valve shaft 34. The first pressure applying portion 94 and the second pressure applying portion 96 are configured to apply, to the first valve seat 70 and the second valve seat 80, the pressure of the fluid leaking through the slight gap between the outer peripheral surface of the valve shaft 34 and the inner peripheral surface of the valve seat 8. Thus, in the three-way motor valve 1 according to the first embodiment, even when there is a difference in pressure between the second valve port 18 and the first valve port 9, a relatively high pressure of the fluid is applied to the first pressure applying portion 94 and the second pressure applying portion 96 through the slight gap between the outer peripheral surface of the valve shaft 34 and the inner peripheral surface of the valve seat 8. As a result, owing to the relatively high pressure of the fluid of about 100 KPa, which is applied to the first pressure applying portion 94, the first valve seat 70 under a relatively low pressure of about 100 KPa is operated so as to restore the valve shaft 34 to a proper position. Therefore, the three-way motor valve 1 according to the first embodiment can prevent and suppress the valve shaft 34 from being moved (displaced) to the side of the first valve port 9 under a relatively low pressure due to the difference in pressure between the second valve port 18 and the first valve port 9, can keep a state in which the valve shaft 34 is smoothly supported by the bearing 41, and can prevent and suppress an increase in driving torque when the valve shaft 34 is driven to rotate in the direction of closing the valve shaft 34.

Further, the three-way motor valve 1 according to the first embodiment similarly operates also under a state in which the first valve port 9 is nearly completely opened, that is, the second valve port 18 is nearly completely closed, and thus can prevent and suppress the increase in driving torque when the valve shaft 34 is driven to rotate.

Examples of a fluid (brine) used for the three-way motor valve 1 according to the first embodiment include fluorine-based inert liquids such as Opteon (trademark: manufactured by Chemours-Mitsui Fluoroproducts Co., Ltd.) and Novec (trademark: manufactured by 3M company), which are adaptable and used, for example, at a pressure of from 0 MPa to 1 MPa and in a temperature range of from about −85° C. to about +120° C.

When an outflow amount of the fluid having a temperature of about −85° C. is switched in the three-way motor valve 1, a temperature of the valve main body 6 itself through which the fluid flows becomes equal to about −85° C.

In the three-way motor valve 1, the first spring energized seals 120 and 140 and the second spring energized seals 130 and 150 are used so as to hermetically seal (seal) the gaps between the first valve seat 70 and the second valve seat 80 and the first flow passage forming member 15 and the second flow passage forming member 25 and the gaps between the first flow passage forming member 15 and the second flow passage forming member 25 and the valve main body 6. Further, the first spring energized seals 120 and 140 and the second spring energized seals 130 and 150 are arranged so as to be opened toward the first pressure applying portion 94 and the second pressure applying portion 96, respectively. Further, the first spring energized seal 120 includes a combination of the spring member 121 made of metal and the sealing member 122 made of a synthetic resin. Not only the spring member 121 made of metal but also polytetrafluoroethylene (PTFE), which is a synthetic resin for forming the sealing member 122, is excellent in heat resistance. Thus, polytetrafluoroethylene can withstand long time of use at temperatures of about −85° C. as a lowest temperature and about 260° C. as a highest temperature. This applies to the other first spring energized seal 140 and the second spring energized seals 130 and 150.

Thus, the three-way motor valve 1 according to the first embodiment can improve sealability to a fluid having a low temperature of about −85° C. in comparison to a case in which the first flow passage forming member and the second flow passage forming member, which are mounted to the valve main body 6 and form the first outflow port 7 and the second outflow port 17, are not provided to the first pressure applying portion and the second pressure applying portion, the first flow passage forming member and the second flow passage forming member each having both ends in the longitudinal direction being sealed by the sealing means, which is made of a synthetic resin, has a substantially U-shaped cross section, and is urged in the opening direction by the spring member made of metal, and the gaps between the first valve seat 70 and the second valve seat 80 and the first flow passage forming member 15 and the second flow passage forming member 25 and the gaps between the first flow passage forming member 15 and the second flow passage forming member 25 and the valve main body 6 are sealed with O-rings.

Specifically, when the gaps between the first valve seat 70 and the second valve seat 80 and the first flow passage forming member 15 and the second flow passage forming member 25 and the gaps between the first flow passage forming member 15 and the second flow passage forming member 25 and the valve main body 6 are sealed with the first spring energized seals 120 and 140 and the second spring energized seals 130 and 150, high sealability can be achieved even to a fluid having a low temperature of about −85° C. Further, the first spring energized seals 120 and 140 and the second spring energized seals 130 and 150 each have a relatively large contact area between the first valve seat 70 and the second valve seat 80 and the first flow passage forming member 15 and the second flow passage forming member 25 and between the first flow passage forming member 15 and the second flow passage forming member 25 and the valve main body 6. Also in this regard, high sealability can be achieved.

### INDUSTRIAL APPLICABILITY

The present invention can provide a temperature control device capable of controlling, with high accuracy, a temperature of a fluid for temperature control to be supplied to a temperature control target in comparison to a case in which there is not provided control means for controlling temperature adjustment performance of supply means based on a result of detection performed by detection means for detecting a heat load of the temperature control target.

### REFERENCE SIGNS LIST

100 temperature control device
101 fluid for temperature control
102 temperature adjustment target device
103 supply pipe
104 fluid supply portion
105 detection means
106 storage tank
109 first three-way valve for flow rate control
110 first temperature sensor
111 second temperature sensor
117 second three-way valve for flow rate control

1. A temperature control device, comprising:
supply means for adjusting a fluid for temperature control to a predetermined temperature and then supplying the fluid for temperature control;
detection means for detecting a heat load of a temperature control target to be supplied with the fluid for temperature control from the supply means, the detection means being arranged on the temperature control target side; and
control means for controlling temperature adjustment performance of the supply means based on a result of detection performed by the detection means.

2. The temperature control device according to claim 1, wherein the detection means includes:
a first three-way valve for flow rate control configured to split the fluid for temperature control from the supply means into the fluid for temperature control to be supplied to the temperature control target and the fluid for temperature control to be returned to the supply means without being supplied to the temperature control target;
first temperature detection means for detecting a temperature of the fluid for temperature control to be supplied to the temperature control target by the first three-way valve for flow rate control; and
second temperature detection means for detecting a temperature of the fluid for temperature control returned from the temperature control target.

3. The temperature control device according to claim 1, wherein the supply means includes:
first supply means for supplying a lower temperature fluid adjusted to a first predetermined lower temperature; and
second supply means for supplying a higher temperature fluid adjusted to a second predetermined higher temperature, and
wherein the detection means includes:
a second three-way valve for flow rate control configured to mix the lower temperature fluid supplied from the first supply means and the higher temperature fluid supplied from the second supply means while controlling a flow rate of the lower temperature fluid and a flow rate of the higher temperature fluid to form the fluid for temperature control and then supply the fluid for temperature control to the temperature control target;
a third three-way valve for flow rate control configured to distribute the fluid for temperature control having flowed through the temperature control target to the first supply means and the second supply means while controlling a flow rate of the fluid for temperature control;
first temperature detection means for detecting a temperature of the fluid for temperature control to be supplied to the temperature control target by the second three-way valve for flow rate control; and
second temperature detection means for detecting a temperature of the fluid for temperature control returned from the temperature control target.

4. The temperature control device according to claim 1, wherein the control means controls the temperature adjustment performance of the supply means by increasing and decreasing a flow rate of a heat exchange medium that adjusts a temperature of the fluid for temperature control through intermediation of a heat exchanger in the supply means.

5. The temperature control device according to claim 2, wherein the control means calculates the heat load of the temperature control target based on a flow rate of the fluid for temperature control to be supplied to the temperature control target and results of detection performed by the first temperature detection means and the second temperature detection means, which are included in distribution information of the first three-way valve for flow rate control.

6. The temperature control device according to claim 5, wherein the control means controls temperature adjustment performance F1 of the supply means based on a result H1 of calculation of the heat load of the temperature control target by an arithmetic expression:
F1=((H1−b)/a)^{0.5}

7. The temperature control device according to claim 6, wherein the control means controls an rpm of a drive source configured to drive a chiller in the supply means.

8. The temperature control device according to claim 1, wherein the control means controls a distribution ratio at the first three-way valve for flow rate control.

9. The temperature control device according to claim 1, wherein the supply means includes a fourth three-way valve for flow rate control configured to split the fluid for temperature control from the supply means into the fluid for temperature control to be supplied to the temperature control target and the fluid for temperature control to be returned without being supplied to the temperature control target.

10. The temperature control device according to claim 9, wherein the control means controls a flow rate of the fluid for temperature control flowing into the fourth three-way valve for flow rate control to a constant value.

11. The temperature control device according to claim 1, wherein the supply means includes:
a storage tank configured to store the fluid for temperature control returned from the temperature control target; and
cooling means for cooling the fluid for temperature control stored in the storage tank.

12. The temperature control device according to claim 2, wherein the first three-way valve for flow rate control includes:
an inflow port, which allows inflow of the fluid for temperature control; and
a first valve port and a second valve port, which allow the fluid for temperature control flowing in through the inflow port to be split into the fluid for temperature control to be supplied to the temperature control target and the fluid for temperature control to be returned to the supply means without being supplied to the temperature control target.
